(19) United States
(12) Patent Application Publication
(10) Pub. No.: US 2010/0208510 A1
(43) Pub. Date: Aug. 19, 2010

(54) SEMICONDUCTOR MEMORY DEVICE AND METHOD OF OPERATING THE SAME

(75) Inventors: Koji HOSONO, Fujisawa-shi (JP); Hiroshi Maejima, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Toshiba, Tokyo (JP)

(21) Appl. No.: 12/707,298

(22) Filed: Feb. 17, 2010

(30) Foreign Application Priority Data
Feb. 18, 2009 (JP) 2009-035534

(51) Int. Cl. G11C 11/00; G11C 29/00

(52) U.S. Cl. 365/148; 365/200

(57) ABSTRACT

A semiconductor memory device comprises: a memory cell array having memory cells disposed at a crossing-point of a plurality of first lines and a plurality of second lines; and a control circuit configured to apply a first voltage to selected one of the first lines, and to apply a second voltage to selected one of the second lines. The control circuit comprises: a first isolation latch circuit configured to set the first lines to a floating state; and a second isolation latch circuit configured to set the second lines to the floating state. During a forming operation, the first and second isolation latch circuits set one of the first lines and one of the second lines to which a defective memory cell is connected to the floating state, the defective memory cell being one of the memory cells that allows a current to flow due to application of a voltage.

### CROSS REFERENCE TO RELATED APPLICATIONS

This application is based upon and claims the benefit of priority from prior Japanese Patent Application No. 2009-35534, filed on Feb. 18, 2009, the entire contents of which are incorporated herein by reference.

### BACKGROUND OF THE INVENTION

1. Field of the Invention

The present invention relates to a semiconductor memory device and a method of operating the same.

2. Description of the Related Art

In recent years, resistive memory devices utilizing a variable resistor as a memory element are receiving attention as candidates to succeed flash memory. The resistive memory devices herein include resistive RAM (ReRAM), in a narrow sense, that uses a transition metal oxide as a recording layer and stores its resistance states in a non-volatile manner, as well as Phase Change RAM (PCRAM) that uses chalcogenide or the like as a recording layer to utilize the resistance information of crystalline states (conductors) and amorphous states (insulators). The variable resistor in this resistive memory is in a constant high-resistance state with an unchanging resistance value immediately subsequent to manufacture. The variable resistor in this state undergoes an operation (hereinafter referred to as “forming operation”) in which it is applied with a certain voltage, whereby the variable resistor becomes capable of transition of resistance states and therefore functional as a memory element.

Two kinds of operation modes in memory cells of resistive memory devices are known. In one kind, known as a bipolar type, a high-resistance state and a low-resistance state are set by switching a polarity of an applied voltage. In the other kind, known as a unipolar type, setting of the high-resistance state and the low-resistance state are made possible by controlling a voltage value and a voltage-application time, without switching the polarity of the applied voltage.

The unipolar type is preferable for realizing a high-density memory cell array. This is because, in the case of the unipolar type, the cell array can be configured by overlapping a variable resistor and a rectifier such as a diode at crossing-points of bit lines and word lines, without using a transistor. Furthermore, arranging such memory cell arrays three-dimensionally in stacks enables a large capacity to be realized without causing an increase in cell array area (refer to Japanese Unexamined Patent Application Publication (Translation of PCT Application) No. 2002-541613).

In the case of unipolar type ReRAM, write of data to a memory cell is performed by applying for a short time to the variable resistor a certain voltage. As a result, the variable resistor changes from the high-resistance state to the low-resistance state. Hereinafter, this operation to change the variable resistor from the high-resistance state to the low-resistance state is called a setting operation. In contrast, erase of data in a memory cell is performed by applying for a long time to the variable resistor in the low-resistance state subsequent to the setting operation a certain voltage lower than that applied during the setting operation. As a result, the variable resistor changes from the low-resistance state to the high-resistance state. Hereinafter, this operation to change the variable resistor from the low-resistance state to the high-resistance state is called a resetting operation. The memory cell, for example, has the high-resistance state as a stable state (reset state), and, in the case of binary data storage, data write is performed by the setting operation which changes the reset state to the low-resistance state.

During an operation on a memory cell (for example, the setting operation), a selected bit line is applied with a certain voltage (for example, a voltage V_set in the case of the setting operation), and a selected word line is applied with a voltage 0 V. An unselected bit line and an unselected word line are applied with, respectively, 0 V and a certain voltage. As a result, a desired potential difference is applied only to a selected memory cell connected to the selected bit line and the selected word line, and unselected other memory cells are in a reverse bias state or a state in which no potential difference is applied.

In manufacturing processes of this resistive memory, defective memory cells are sometimes formed. Defective memory cell refers to a memory cell in which the rectifier and the variable resistor provided at the crossing-point of the bit line and the word line are for some reason unable to perform their functions, such that application of a voltage in a reverse direction as well as in a forward direction results in easy flow of current. This defective memory cell is hereinafter referred to as Cross Point Failure (CPF).

If a CPF exists in the memory cell array of the resistive memory device, trouble arises when executing the forming operation on each of the memory cells subsequent to formation of the memory cell array, and when executing the setting, resetting, and read operations. This is because, although, in these operations, a voltage is applied to the unselected bit line and the unselected word line such that the unselected memory cell is in a reverse bias state or a state in which no potential difference is applied, this voltage is sometimes applied to an undesired bit line or word line via the CPF. To improve yield of the resistive memory device it is required that stable operation in a normal memory cell be realized even in a memory cell array having a CPF.

### SUMMARY OF THE INVENTION

A semiconductor memory device in accordance with a first aspect of the present invention comprises: a memory cell array having memory cells disposed at a crossing-point of a plurality of first lines and a plurality of second lines, each of the memory cells being configured by a rectifier and a variable resistor connected in series; and a control circuit configured to apply a first voltage to selected one of the first lines, and to apply a second voltage to selected one of the second lines, such that a certain potential difference is applied to selected one of the memory cells disposed at the crossing-point of the selected one of the first lines and the selected one of the second lines, the control circuit comprising: a first isolation latch circuit configured to set the first lines to a floating state in which a voltage is not applied, based on an address signal; and a second isolation latch circuit configured to set the second lines to the floating state in which a voltage is not applied, based on an address signal, during execution of a forming operation configured to render a resistance state of the variable resistor capable of transition by applying a certain potential difference to the selected one of the memory cells, the first and second isolation latch circuits setting one of the first lines and one of the second lines to which a defective memory cell is connected to the floating state, the defective memory cell being one of the memory cells that allows a current to flow due to application of a voltage in a reverse direction as well as in a forward direction.

A semiconductor memory device in accordance with a second aspect of the present invention comprises: a memory cell array having memory cells disposed at a crossing-point of a plurality of first lines and a plurality of second lines, each of the memory cells being configured by a rectifier and a variable resistor connected in series; and a control circuit configured to apply a first voltage to selected one of the first lines, and to apply a second voltage to selected one of the second lines, such that a certain potential difference is applied to selected one of the memory cells disposed at the crossing-point of the selected one of the first lines and the selected one of the second lines, the control circuit comprising: a first isolation latch circuit configured to set the first lines to a floating state in which a voltage is not applied, based on an address signal; and a second isolation latch circuit configured to set the second lines to the floating state in which a voltage is not applied, based on an address signal, other of the memory cells connected to one of the first lines and one of the second lines to which a defective memory cell is connected being in an unformed state in which a resistance state of the variable resistor does not undergo transition, the defective memory cell being one of the memory cells that allows a current to flow due to application of a voltage in a reverse direction as well as in a forward direction, and during execution of an operation by applying a certain voltage to the selected one of the memory cells, the first and second isolation latch circuits setting at least one of the one of the first lines and the one of the second lines to which the defective memory cell is connected to the floating state.

A method of operating a semiconductor memory device in accordance with a third aspect of the present invention, the semiconductor memory device including a memory cell array having memory cells disposed at a crossing-point of a plurality of first lines and a plurality of second lines, each of the memory cells being configured by a rectifier and a variable resistor connected in series, and a control circuit configured to apply a first voltage to selected one of the first lines, and to apply a second voltage to selected one of the second lines, such that a certain potential difference is applied to selected one of the memory cells disposed at the crossing-point of the selected one of the first lines and the selected one of the second lines, the method comprises: setting one of the first lines and one of the second lines to which a defective memory cell is connected to a floating state, the defective memory cell being one of the memory cells that allows a current to flow due to application of a voltage in a reverse direction as well as in a forward direction, and executing a forming operation to render a resistance state of the variable resistor capable of transition by applying a certain potential difference to the selected one of the memory cells.

### BRIEF DESCRIPTION OF THE DRAWINGS

FIG. 1A is a view showing a memory cell array of a resistive memory device in an embodiment of the present invention.

FIG. 1B is a table describing an applied voltage in the resistive memory device in the embodiment of the present invention.

FIG. 2 is a view showing the memory cell array of the resistive memory device in the embodiment of the present invention.

FIG. 3 is a view showing a voltage-application state during a forming operation of the resistive memory device in the embodiment of the present invention.

FIG. 4 is a view showing a voltage-application state during a forming operation of a resistive memory device in a comparative example.

FIG. 5 is a block diagram showing a configuration of peripheral circuits of the resistive memory device in the embodiment of the present invention.

FIG. 6A is a circuit diagram describing details of a column decoder in the embodiment of the present invention.

FIG. 6B is a circuit diagram describing details of the column decoder in the embodiment of the present invention.

FIG. 6C is a circuit diagram describing details of the column decoder in the embodiment of the present invention.

FIG. 7A is a circuit diagram describing details of a global row decoder in the embodiment of the present invention.

FIG. 7B is a circuit diagram describing details of the global row decoder in the embodiment of the present invention.

FIG. 8 is a timing chart describing the forming operation in the resistive memory device of a first embodiment.

FIG. 9 is a view describing the forming operation in the resistive memory device of the first embodiment.

FIG. 10 is a view describing the forming operation in the resistive memory device of the first embodiment.

FIG. 11 is a view describing the forming operation in the resistive memory device of the first embodiment.

FIG. 12 is a view describing the forming operation in the resistive memory device of the first embodiment.

FIG. 13 is a view describing a setting operation in a resistive memory device of a second embodiment.

FIG. 14 is a view describing the setting operation in the resistive memory device of the second embodiment.

FIG. 15 is a view describing the setting operation in the resistive memory device of the second embodiment.

### DETAILED DESCRIPTION OF THE EMBODIMENTS

Embodiments of the present invention are now described in detail with reference to the accompanying drawings. A semiconductor memory device described in the present embodiments is a resistive memory device having a three-dimensional memory cell array structure in which memory cell arrays are stacked. However, it goes without saying that this configuration is no more than an example, and that the present invention is not limited to this configuration.

### First Embodiment

### Configuration of a Semiconductor Memory Device in Accordance with a First Embodiment

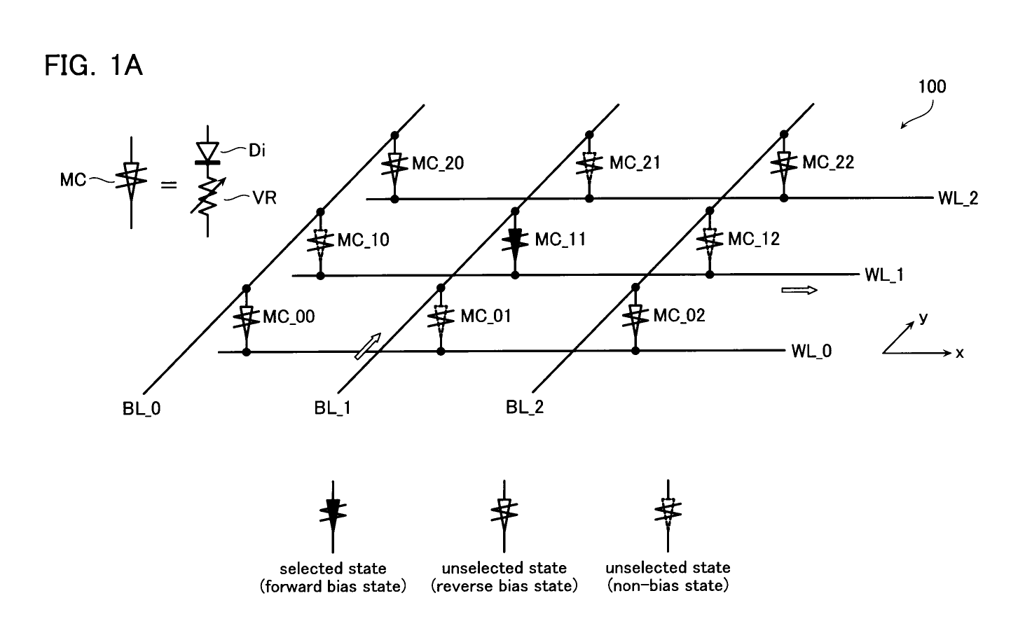

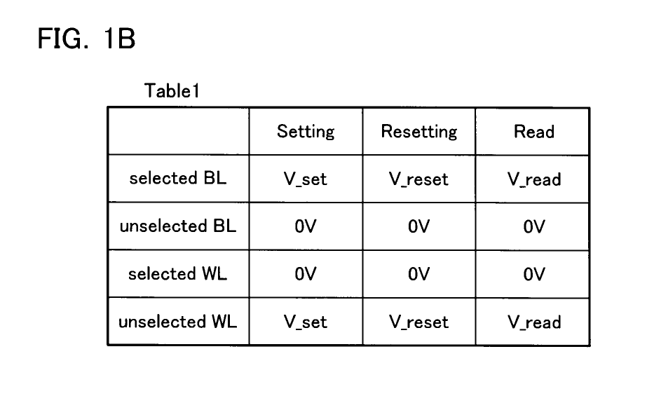

FIG. 1A is a view showing an example of a part of a layout of a memory cell array 100 in a resistive memory device in accordance with a first embodiment of the present invention. As shown in FIG. 1A, the resistive memory device of a unipolar type has resistive-type unit memory cells MC disposed at respective crossing-points of mutually-intersecting bit lines BL and word lines WL, the resistive-type unit memory cell MC having a rectifier, for example, a diode Di, and a variable resistor VR connected in series. Here, the bit lines BL are assumed to be signal lines connected to an anode side of the diode Di and the word lines WL are assumed to be signal lines connected to a cathode side of the diode Di. Moreover, the memory cells MC configured by the diode Di and the variable resistor VR connected in series are expressed using symbols shown in the figure. This applies similarly to the example below. Here, a disposition and polarity of the diode Di and variable resistor VR comprising the memory cell MC are likewise not limited to what is shown in the figure. The memory cell array 100 shown in FIG. 1A has, for example, 1×10³ unit memory cells MC disposed respectively in a longitudinal direction of the bit line BL (y direction shown in FIG. 1A) and a longitudinal direction of the word line WL (x direction shown in FIG. 1A), the unit memory cells MC being arranged in a two-dimensional matrix.

The variable resistor VR is, for example, one having a structure comprising electrode/transition metal oxide/electrode or the like, in which applied conditions of voltage, current, heat and so on cause a resistance of the metal oxide to vary, and stores those differing states of resistance as information in a nonvolatile manner. Utilizable as the variable resistor VR are, more specifically, for example, ones like chalcogenide or the like in which the resistance is varied due to phase transition between a crystalline state and an amorphous state (PCRAM), ones in which the resistance is varied by precipitating metal cations to form a contacting bridge between the electrodes and ionizing the precipitated metal to destroy the contacting bridge (CBRAM: Conductive Bridging RAM), and ones in which the resistance is varied by voltage or current application (broadly divided into ones in which a resistance variation occurs due to presence/absence of a trapped charge in a charge trap existing in an electrode interface and ones in which a resistance variation occurs due to presence/absence of a conductive path induced by oxygen deficiency or the like) (ReRAM).

In the case of unipolar type ReRAM, write of data to the memory cell MC is performed by applying to the variable resistor VR a voltage of, for example, 3.5 V (actually about 4.5 V if a voltage drop portion of the diode Di is included) and a current of about 10 nA for a time of about 10 ns-100 ns. This causes the variable resistor VR to change from the high-resistance state to the low-resistance state (setting operation).

On the other hand, erase of data in the memory cell MC is performed by applying to the variable resistor VR in the low-resistance state subsequent to the setting operation a voltage of 0.8 V (actually about 1.8 V if a voltage drop portion of the diode Di is included) and a current of about 1 μA-10 μA for a time of about 500 ns-2 μs. This causes the variable resistor VR to change from the low-resistance state to the high-resistance state (resetting operation).

A read operation of the memory cell MC is performed by applying to the variable resistor VR a voltage of 0.4 V (actually about 1.4 V if a voltage drop portion of the diode Di is included) and monitoring a current flowing via the variable resistor VR using a sense amplifier. This allows judgement of whether the variable resistor VR is in the high-resistance state or the low-resistance state. Note that, when two bits of data can be stored in one memory cell MC, the sense amplifier generates three different kinds of reference voltages and compares these reference voltages and a cell signal.

As shown in Table 1 of FIG. 1B, during operation of the resistive memory device, there are four kinds of voltage-application states in the bit lines BL and word lines WL of the memory cell array 100. As a result, there exist three kinds of voltage-application states in the memory cell MC. The voltage-application states in the memory cell MC are described below taking those during the setting operation as an example. In FIG. 1A, selected bit line BL and selected word line WL are bit line BL_1 and word line WL_1, and these are applied with a selected bit line voltage V_set and a selected word line voltage (for example, 0 V), respectively. Unselected bit lines BL and unselected word lines WL are bit lines BL_0 and BL_2, and word lines WL_0 and WL_2, and these are applied with an unselected bit line voltage (for example, 0 V) and an unselected word line voltage V_set, respectively.

The memory cell MC_11 connected to the crossing-point of the selected bit line BL_1 and the selected word line WL_1 shown in FIG. 1A is hereafter assumed to be in a selected state (forward bias state) and expressed by the symbol in the figure. A setting voltage V_set is applied to the memory cell MC_11 in the selected state from the selected bit line BL_1 (voltage V_set) to the selected word line WL_1 (voltage 0 V) in a forward direction of the diode Di. As a result, a potential difference V_set is applied to the selected memory cell MC_11, whereby the variable resistor VR is changed from the high-resistance state to the low-resistance state, thus completing the setting operation.

The memory cells MC_01 and MC_21 connected to crossing-points of the selected bit line BL_1 and the unselected word lines WL_0 and WL_2 shown in FIG. 1A are hereafter assumed to be in an unselected state (non-bias state) and expressed by the symbol in the figure. Similarly, the memory cells MC_10 and MC_12 connected to crossing-points of the selected word line WL_1 and the unselected bit lines BL_0 and BL_2 are hereafter likewise assumed to be in the unselected state (non-bias state) and expressed by the symbol in the figure. The same voltage (voltage V_set) is applied to the unselected word lines WL_0 and WL_2 as to the selected bit line BL_1. Similarly, the same voltage (voltage 0 V) is applied to the unselected bit lines BL_0 and BL_2 as to the selected word line WL_1. As a result, there is no potential difference in the memory cells MC in the unselected state (non-bias state) and no flow of current therein.

The memory cells MC_00, MC_20, MC_02, and MC_22 connected to crossing-points of the unselected word lines WL_0 and WL_2 and the unselected bit lines BL_0 and BL_2 shown in FIG. 1A are hereafter assumed to be in an unselected state (reverse bias state) and expressed by the symbol in the figure. A voltage is applied to the memory cells MC in the unselected state (reverse bias state) from the unselected word lines WL (voltage V_set) to the unselected bit lines BL (voltage 0 V) in a reverse bias direction of the diode Di. As a result, there is likewise no flow of current in the memory cells MC in the unselected state (reverse bias state).

Such a voltage-application method enables a desired voltage to be applied only to the selected memory cell MC_11 in the selected state. In the resetting operation and the read operation, similar operations to those during the above-mentioned setting operation are executed with changes to values of voltages applied to the bit lines and word lines.

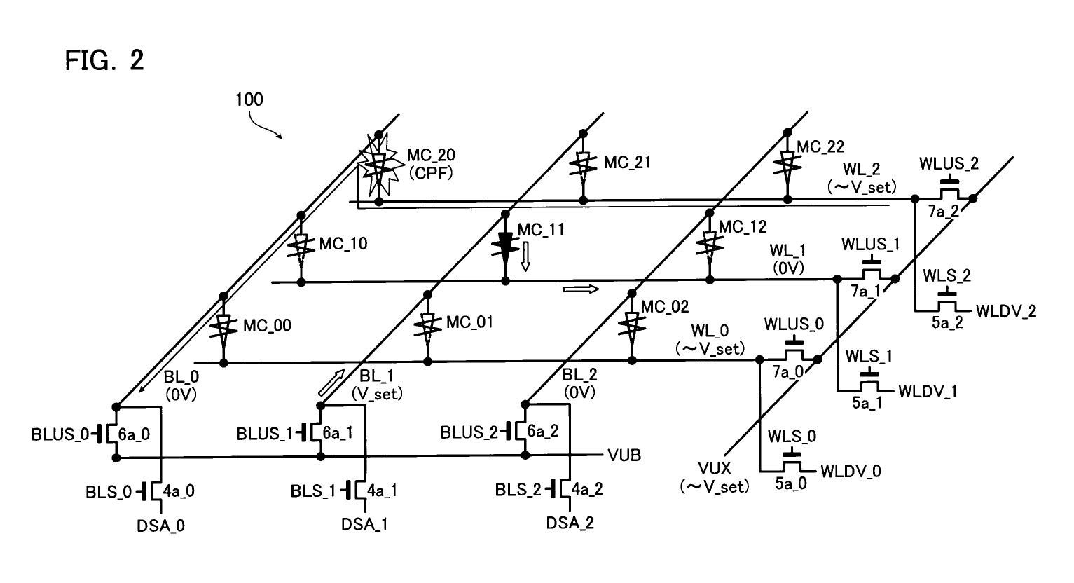

Next, the case where a defective memory cell, in other words a CPF, exists in this memory cell array 100 is described with reference to FIG. 2. FIG. 2 is a view showing an example where a CPF exists in the memory cell array 100 in accordance with the present embodiment. In the present embodiment, description proceeds assuming memory cell MC_20 to be the CPF. The memory cell MC_20 is in a state where current flows easily due to application of a voltage in a reverse direction as well as in a forward direction.

Connected to bit lines BL_0-BL_2 in the memory cell array 100 shown in FIG. 2 are NMOS transistors 4a (4a_0-4a_2) and NMOS transistors 6a (6a_0-6a_2), respectively. The bit lines BL_0-BL_2 are selected by the transistors 4a and 6a as part of a column decoder, and have a potential thereof controlled. The transistors 4a_0-4a_2 are respectively connected to signal lines DSA_0-DSA_2 and controlled by signals BLS_0-BLS_2 inputted to gates thereof. Furthermore, the transistors 6a_0-6a_2 are connected to a signal line VUB and controlled by signals BLUS_0-BLUS_2 inputted to gates thereof.

The signal lines DSA_0-DSA_2 are connected to a sense amplifier and a write control circuit to be described hereafter. The sense amplifier and the write control circuit apply a selected bit line voltage to any one of the signal lines DSA_0-DSA_2, and execute the setting and resetting operations, and the read operation on a selected memory cell MC. The signal line VUB is a signal line configured to control a potential applied to an unselected bit line.

Similarly, connected to word lines WL_0-WL_2 are, likewise, NMOS transistors 5a (5a_0-5a_2) and NMOS transistors 7a (7a_0-7a_2), respectively. The word lines WL_0-WL_2 are selected by the transistors 5a and 7a as part of a row decoder, and have a potential thereof controlled. The transistors 5a_0-5a_2 are respectively connected to signal lines WLDV_0-WLDV_2 and controlled by signals WLS_0-WLS_2 inputted to gates thereof. Furthermore, the transistors 7a_0-7a_2 are connected to a signal line VUX and controlled by signals WLUS_0-WLUS_2 inputted to gates thereof.

Each of the signal lines WLDV_0-WLDV_2 serves as an address signal line. A selected one from among the signal lines WLDV_0-WLDV_2 is provided with a selected word line voltage applied from the row decoder. The signal line VUX is a signal line configured to control a potential applied to an unselected word line.

FIG. 2 shows voltage-application states during the setting operation when memory cell MC_11 is assumed to be the selected memory cell, similarly to FIG. 1A. The selected bit line BL_1 is applied with the selected bit line voltage V_set supplied from the signal line DSA_1 via the transistor 4a_1. Other unselected bit lines are applied with an unselected bit line voltage of, for example, 0 V supplied from the signal line VUB via the transistors 6a_0 and 6a_2.

The selected word line WL_1 is applied with the selected word line voltage of, for example, 0 V supplied from the signal line WLDV_1 via the transistor 5a_1. Other unselected word lines are applied with an unselected word line voltage V_set supplied from the signal line VUX via the transistors 7a_0 and 7a_2.

Here, the memory cell array 100 shown in FIG. 2 illustrates the case where the memory cell MC_20 is the CPF. In the CPF portion, the bit line BL_0 and the word line WL_2 are short-circuited, and the potential V_set of the signal line VUX which is to be applied to the unselected word line WL_2 changes to an intermediate potential in accordance with the voltage 0 V of the bit line BL_0. During the setting operation, the memory cell MC_21 connected to the identical word line WL_2 as the CPF attains the forward bias state due to the selected bit line voltage V_set and the potential of the word line WL_2 changed to the intermediate potential. Now, if the memory cell MC_21 is assumed to be in the low-resistance state, a significant current drains from the bit line BL_1 to the word line WL_2 via the memory cell MC_21.

In addition, the short circuit between the bit line BL_0 and the word line WL_2 causes the potential 0 V of the signal line VUB which is to be applied to the unselected bit line BL_0 to change to an intermediate potential in accordance with the voltage V_set of the word line WL_2. During the setting operation, the memory cell MC_10 connected to the identical bit line BL_0 as the CPF attains the forward bias state due to the potential of the bit line BL_0 changed to the intermediate potential and the selected word line voltage 0 V. Now, if the memory cell MC_10 is assumed to be in the low-resistance state, there is a possibility of an unforeseen current flowing from the bit line BL_0 into the selected word line WL_1 via the memory cell MC_10.

An unintended flow of current via the memory cells MC_21 and MC_10 is caused by the potential of the unselected word line WL_2 and the unselected bit line BL_0 being different from a usual potential. The nearer the memory cell lies to the CPF, the greater the effect of this leak of current and the more difficult it is to operate normally. Although the case of one CPF is described in FIG. 2, in cases where there are a large number of CPFs in the memory cell array 100 and where they occur in places extremely close to a control transistor of the word lines WL and bit lines BL, there is a possibility of the current passing through the CPFs producing an effect on the whole of the memory cell array 100.

Accordingly, the resistive memory device in accordance with the embodiment of the present invention utilizes the fact that a memory cell does not exhibit the behaviour of transition of resistance state (change between the set state and the reset state) unless it undergoes the forming operation. That is, memory cells connected to bit lines and word lines that include a CPF are not subject to the forming operation, and are left in an unformed state (constant high-resistance state). As a result, various operations can be executed on other normal memory cells despite the existence of CPFs, as described in detail hereafter.

An operation to form memory cells in the unformed state along bit lines and word lines that include a CPF in the present embodiment, and various operations in a memory cell array that includes memory cells in the unformed state in the next embodiment are now described.

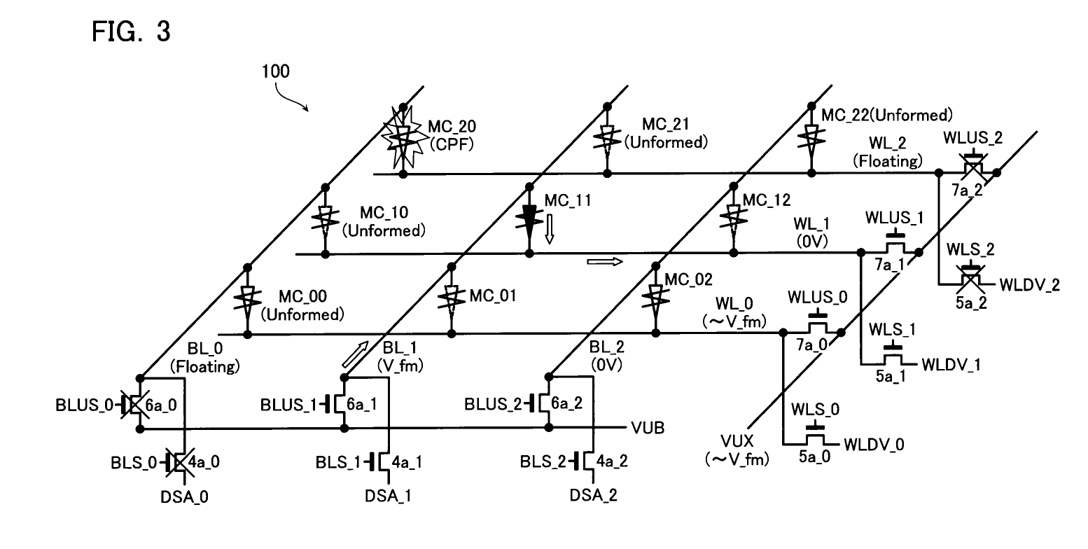

FIG. 3 is a view showing voltage-application states during the forming operation of the resistive memory device in the present embodiment. Here, description proceeds assuming the selected memory cell on which the forming operation is executed to be memory cell MC_11, and the memory cell MC_20 to be a CPF. Note that the CPF is assumed to be detected prior to execution of the forming operation. Since, prior to executing the forming operation on the memory cells, all normal memory cells are still in the constant high-resistance state where the resistance state does not change, it is only required to apply a voltage to all the memory cells within the memory cell array, thereby detecting as a CPF those memory cells in which a current flows.

In the forming operation of the present embodiment, the forming operation is executed such that other memory cells connected to the bit line and the word line that include the CPF are not applied with the voltage required for the forming operation. Therefore, the resistive memory device according to the present embodiment executes the forming operation by setting the bit line BL_0 and the word line WL_2 to which the CPF memory cell MC_20 is connected to the floating state, during the forming operation. Specifically, the transistors 4a_0 and 6a_0 are held in off-state during the forming operation. Similarly, the transistors 5a_2 and 7a_2 are held in off-state during the forming operation. The bit line BL_0 and the word line WL_2 can thereby be set to the floating state, and a voltage is not applied thereto. In this state, the memory cells MC_00, MC_10, MC_21, and MC_22 connected to the identical bit line BL_0 or the identical word line WL_2 as the CPF are not applied with a forming voltage V_fm applied to the selected memory cell MC_11. Conditions, such as voltage-application timing, voltage values, and soon, of this forming operation are described in detail hereafter.

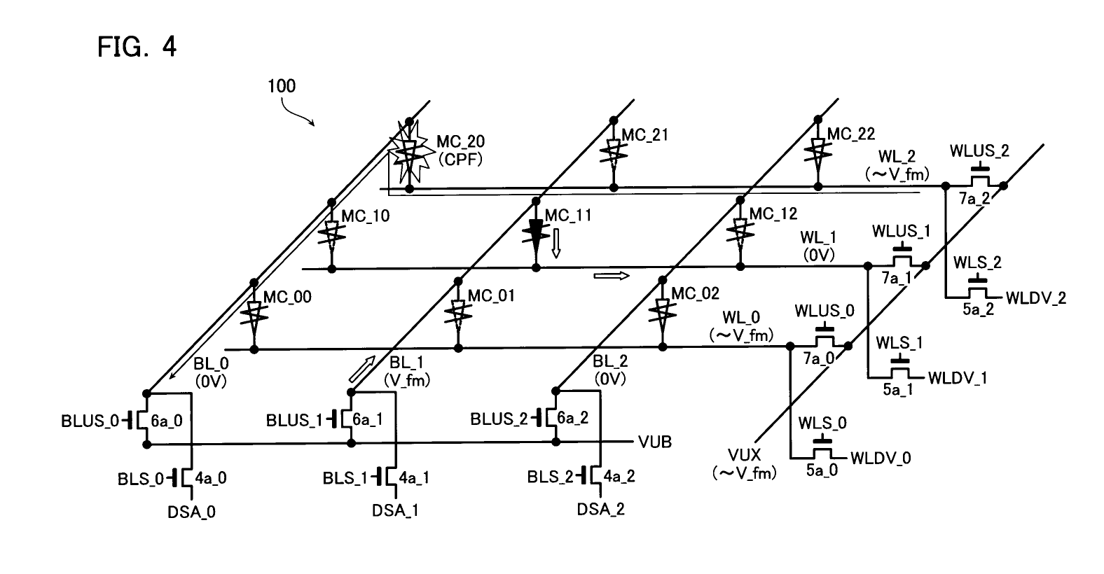

FIG. 4 is a view showing voltage-application states during a forming operation of a resistive memory device in a comparative example. In the resistive memory device in the comparative example, the transistors 4a_0 and 7a_2 are rendered conductive, whereby the bit line BL_0 is applied with the voltage 0 V, and the word line WL_2 is applied with the forming voltage V_fm. In this case, a current flows from the word line WL_2 to the bit line BL_0 via the CPF. There is thereby a risk that the memory cells MC_21 and MC_10 attain an unintended voltage-application state, resulting in the memory cells MC_21 and MC_10 incorrectly undergoing forming, as in the aforementioned description using FIG. 2.

Here, if the bit line BL_0 only is set to the floating state, the memory cell MC_10 may attain a similar voltage-application state to the selected memory cell in the forming operation, since the bit line BL_0 is charged to the forming voltage V_fm. Moreover, if the word line WL_2 only is set to the floating state, the memory cell MC_21 attains a similar voltage-application state to the selected memory cell in the forming operation, since the word line WL_2 is discharged to a voltage (for example, 0 V) of the signal line VUB.

Accordingly, in the resistive memory device in accordance with the present embodiment, the bit line BL_{—} 0 and the word line WL_2 are both set to the floating state. The unselected memory cells MC_00, MC_10, MC_21, and MC_22 are thereby not applied with the voltage required for the forming operation. Dispersions of floating potential sometimes occur here due to coupling with surrounding bit lines and word lines. However, controlling these dispersions within a certain range enables the unselected memory cells MC_00, MC_10, MC_21, and MC_22 to be controlled so as to be reliably prevented from undergoing forming.

Control circuits of the resistive memory device for setting the bit lines and the word lines to the floating state are now described. Included in the control circuits of the bit lines and the word lines of the resistive memory device are isolation latch circuits for setting the bit lines and the word lines to the floating state.

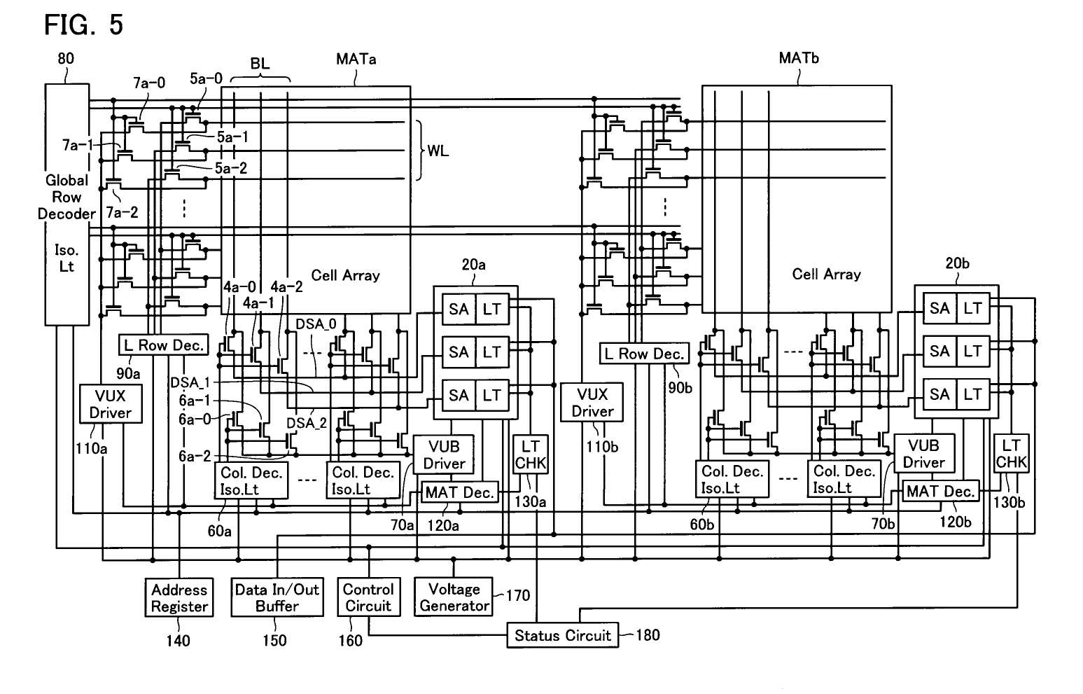

FIG. 5 is a block diagram showing a configuration of peripheral circuits of the resistive memory device. Shown representatively here are two memory mats MAT (MATa and MATb), each having the above-described memory cell array 100 arranged thereon. In the present embodiment, an operation may be executed on one memory mat MATa only, or on a plurality of memory mats MATa and MATb simultaneously. Alternatively, a set of operations comprising a single address specification and operation run may be performed in turn for one of the plurality of memory mats MATa and MATb in a certain order.

Included in the peripheral circuits are data control circuits 20, column decoders 60, unselected bit line drive circuits 70, a global row decoder 80, local row decoders 90, unselected word line drive circuits 110, mat decoders 120, latch data check circuits 130, an address register 140, a data input/output buffer 150, a control circuit 160, a voltage generating circuit 170, and a status circuit 180. Note that configurations required separately for each memory mat MAT such as the column decoders 60 and the row decoders 90 are distinguished in FIG. 5 by the addition of characters a and b.

The bit lines BL are connected to the data control circuit 20 via bit line select transistors 4a_0-4a_2. The data control circuit 20 comprises a sense amplifier circuit SA for detecting read data, a latch circuit LT for temporarily storing the read data and write data, and so on, as described hereafter. The bit lines BL are in addition connected also to bit line select transistors 6a_0-6a_2. When a bit line BL is unselected, it is connected to the unselected bit line drive circuit 70 via the bit line select transistors 6a_0-6a_2 to be supplied with a certain unselected bit line voltage in accordance with an operation.

Furthermore, the word lines WL are connected to the local row decoder 90 via word line select transistors 5a_0-5a_2. The word lines WL are in addition connected also to word line select transistors 7a_0-7a_2. When the word line WL is unselected, it is connected to the unselected word line drive circuit 110 via the word line select transistors 7a_0-7a_2 to be supplied with a certain unselected word line voltage in accordance with an operation.

In this FIG. 5, the row decoder is assumed to have a hierarchical structure of the global row decoder 80, and the local row decoder 90 attached to each of the memory mats MATa and MATb, such that word line selection is performed by the hierarchical structure of row decoders. Note that, in the row decoder of FIG. 5, both the word line select transistors 5a_0-5a_2 and the word line select transistors 7a_0-7a_2 are configured by NMOS transistors. In this case, an output signal of the global row decoder 80 is set as a complementary signal for gate drive of the respective transistors (not shown). Similarly, both the bit line select transistors 4a_0-4a_2 and the bit line select transistors 6a_0-6a_2 are also NMOS transistors, respective gates of the transistors being controlled by two complementary signals outputted from the column decoder 60.

Note that PMOS transistors can be used for the bit line select transistors 4a_0-4a_2 and the word line select transistors 7a_0-7a_2, as described hereafter. In such a case, a decode signal outputted from the column decoder 60 and the global decoder 80 need not be a complementary signal but may also be a single signal. Whether or not a PMOS transistor can be used in a bit line select unit and word line select unit is determined by whether or not a voltage required to be transferred is sufficiently higher than a threshold voltage of the PMOS transistor, or by whether or not the voltage required in the forming operation is higher than a voltage transferred by an NMOS transistor, and so on.

When PMOS transistors are used for the bit line select transistors 4a_0-4a_2, a voltage outputted to the bit line must be at least a value of the threshold voltage Vt of the PMOS transistors with an added margin. The lowest that the selected bit line voltage becomes during read is V_read during the read operation. For example, if a margin of, say, 0.4 V is added to the threshold voltage Vt (about −0.7 to −1 V) of the PMOS transistor, this gives at least 1.4 V; if no problems result from this in operational setting during read, then PMOS transistors may successfully be used.

Moreover, PMOS transistors can be used for the word line select transistors 7a_0-7a_2 in the word line select unit. A minimum value of a voltage outputted to the unselected word line WL is V_read during the read operation. Since the voltage applied to the unselected word line WL can be made higher to some degree than the read voltage V_read applied to the selected bit line BL, it is easier to use PMOS transistors for the word line select transistors 7a_0-7a_2 than in the bit line select unit.

The mat decoder 120 is a decoder for selecting the memory mat MAT. If the bit lines BL and word lines WL are not shared with an adjacent memory mat MAT, the bit lines BL and word lines WL can both be set to 0 V in an unselected memory mat MAT. When the memory mat MATa is selected and the memory mat MATb is unselected, the mat decoder 120a outputs a selected state decode signal, and the mat decoder 120b outputs an unselected state decode signal. As a result, the above-mentioned voltage control required in read and data write due to the setting and resetting operations is performed on the bit lines BL and word lines WL on the selected memory mat MATa side.

On the other hand, on the unselected memory mat MATb side, if the bit lines BL and word lines WL are not shared with an adjacent memory mat MAT, an output signal received from the mat decoder 120b causes all outputs of the local row decoder 90b to become 0 V, and all outputs of the unselected word line drive circuit 110b also to become 0 V. Moreover, both output signals of the data control circuit 20b (potential of signal line DSA) and all outputs of the unselected bit line drive circuit 70b are controlled to be 0 V. It is of course also possible to set the memory mats MATa and MATb to the selected state simultaneously.

The column decoder 60, the global row decoder 80, the local row decoder 90, and the mat decoder 120 operate on the basis of address data supplied from the address register 140. Details are not shown here, but circuits suitable to the embodiment, such as a predecode circuit and a buffer for temporarily latching an address, can be appropriately installed between the address register 140 and the various kinds of decoders, similarly to other common memory devices.

The data input/output buffer 150 relays data exchanges between the chip exterior and circuits in the chip that leads data to the latch circuit LT in the data control circuit 20, and stores data temporarily as required. Circuits may be configured such that commands, addresses and so on are also downloaded to the chip interior via this data input/output buffer 150, as in NAND flash memory. Moreover, operations for write, read and so on of data are controlled by various control signals outputted from the control circuit 160 and by a voltage outputted from the voltage generating circuit 170. The latch data check circuit 130 and the status circuit 180 are provided to fulfill a supporting role in these operation controls. They detect whether or not data stored in a data latch within the data control circuit is in a certain state, and have functions of feeding back the detected result to the control circuit 160 and of enabling a Pass/Fail result in the data write operation to be output to the chip exterior.

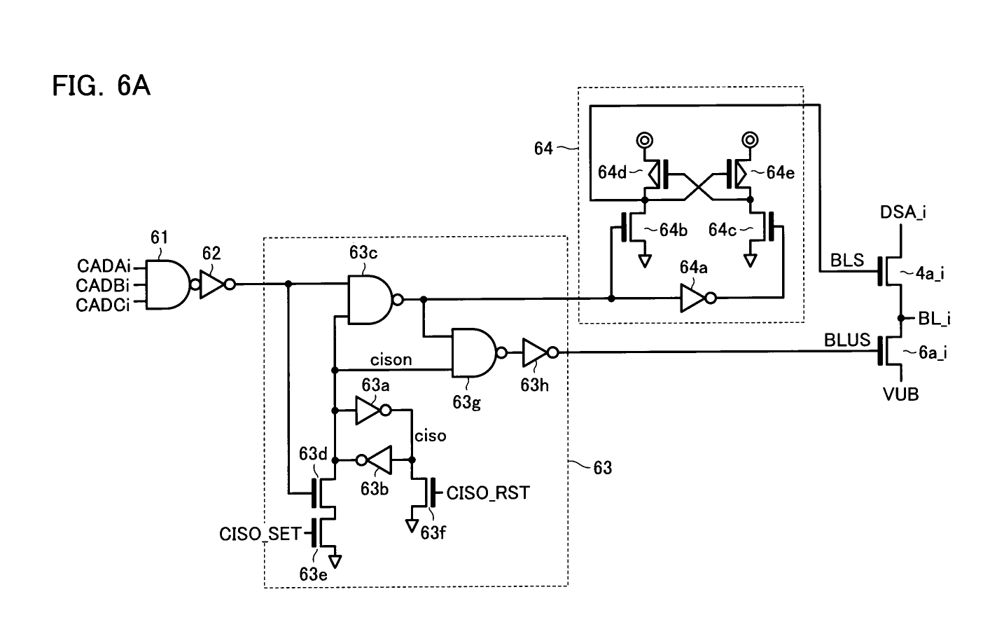

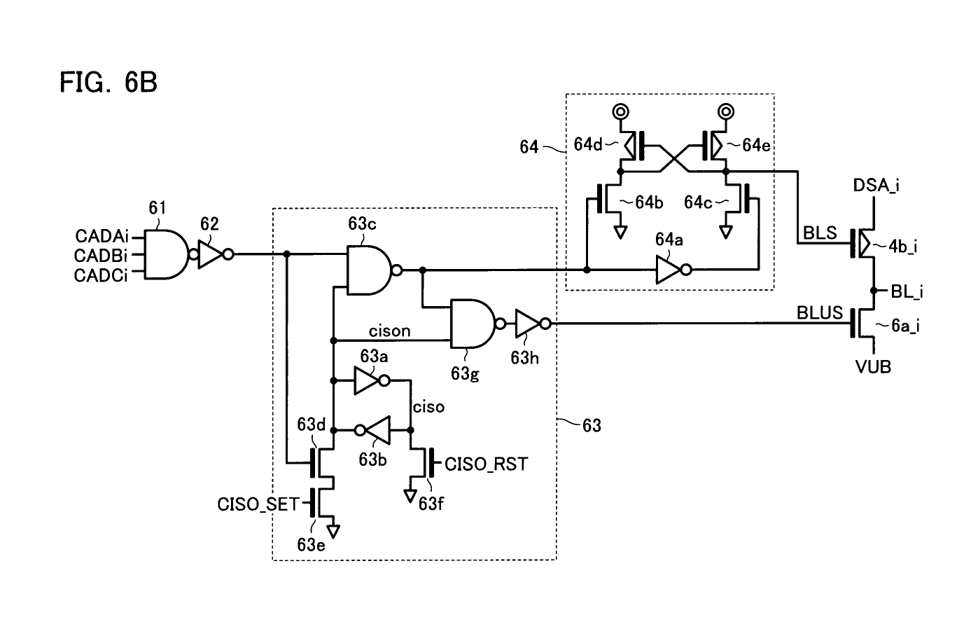

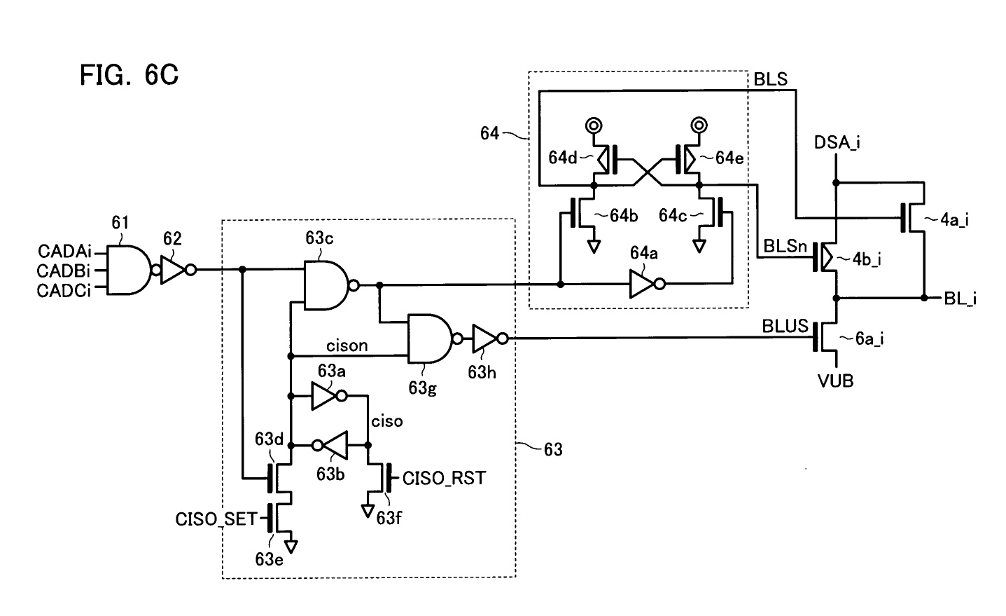

Next, details of the column decoder 60 are described with reference to FIGS. 6A-6C. The column decoder 60 outputs signals BLS and BLUS to control conductive-state/non-conductive-state of the bit line select transistors 4a and 6a. In addition, the column decoder 60 functions also as an isolation latch for setting the bit lines BL_i (i=0-2) to the floating state by rendering both bit line select transistors 4a and 6a non-conductive.

(Configuration of the Column Decoder 60)

In FIG. 6A, a NAND gate 61 is inputted with column address signals CADAi, CADBi, and CADCi. This NAND gate 61 functions as a column decoder. Although details are not shown here, the column address signals CADAi, CADBi, and CADCi are defined to be combinations of address signals that differ for the respective bit lines. An output signal of the NAND gate 61 is inputted to a NAND gate 63c and a gate of an NMOS transistor 63d, via an inverter 62. Inverters 63a, 63b, and 63h, the NAND gate 63c and a NAND gate 63g, and the NMOS transistor 63d and NMOS transistors 63e and 63f configure an isolation latch 63.

The inverters 63a and 63b having input terminals and output terminals connected to each other configure a latch circuit. Note that the inverter 63a has its input terminal defined as node cison and its output terminal defined as node ciso. Connected to a node ciso side is the NMOS transistor 63f for resetting data of the isolation latch. Connected in series to a node cison side are the NMOS transistors 63d and 63e for setting isolation data in the isolation latch. A gate of the transistor 63d is connected to an output terminal of the inverter 62. A gate of the transistor 63f is inputted with a signal CISO_RST, and a gate of the transistor 63e is inputted with a signal CISO_SET. Moreover, sources of the transistors 63e and 63f are grounded. The isolation data held in the isolation latch is controlled by the signals CISO_RST and CISO_SET. The node cison of the isolation latch 63 is connected to respective input terminals of the NAND gates 63c and 63g.

An output signal of the NAND gate 63c is inputted to an NMOS transistor 64b and an inverter 64a that configure a level shifter 64. The level shifter 64 is configured by the inverter 64a, the NMOS transistor 64b and an NMOS transistor 64c, and PMOS transistors 64d and 64e. The inverter 64a is provided such that input signals to gates of the NMOS transistors 64b and 64c are inverted. The gate of the transistor 64b is set as an input terminal of the level shifter 64, and a connection node between the PMOS transistor 64d and the NMOS transistor 64b is set as an output terminal of the level shifter 64. This circuit shows one example of a level shifter circuit, but the level shifter circuit need not necessarily be the shown circuit.

An output signal of the level shifter 64 is inputted as the signal BLS to a gate of an NMOS transistor 4a_{—}i. In addition, an output signal of the NAND gate 63g of the isolation latch 63 is inverted by the inverter 63h to be inputted as the signal BLUS to a gate of an NMOS transistor 6a_{—}i. Connected to a drain of the transistor 4a_{—}i is a signal line DSA_i, and connected to a drain of the transistor 6a_{—}i is the signal line VUB. In FIG. 6A, a bit line BL_i is controlled by the NMOS transistor 4a_{—}i and the NMOS transistor 6a_{—}i. Here, although the case is shown where only one bit line is simultaneously selected by one column address signal, a plurality of lines, for example, eight or sixteen, may be selected. To simplify description in disclosure of this embodiment, description proceeds based on a single bit line BL.

(Operation of the Column Decoder 60)

When the isolation latch 63 is in an unset state, the column decoder 60 connects the bit line BL_i (i=0-2) to the signal line DSA_i (i=0-2) or the signal line VUB. On the other hand, when the isolation latch 63 is in a set state, the column decoder 60 performs control to set the bit line BL_i to the floating state, without connecting the bit line BL_i to either the signal line DSA_i or the signal line VUB.

When the signal CISO_SET is “L” and the signal CISO_RST is “H”, the isolation latch 63 sets the node ciso to “L” and the node cison to “H”. In this case, the isolation latch attains the unset state, whereby the NAND gates 63c and 63g output a signal according to an output signal of the NAND gate 61 that is the column decoder.

When the bit line BL_i is selected in this unset state of the isolation latch, an output signal of the NAND gate 63c becomes “L” and an output signal of the NAND gate 63g becomes “H”. The signal BLS outputted from the level shifter 64 becomes “H” and the signal BLUS becomes “L”, whereby the selected bit line BL_i is controlled by a potential of the signal line DSA_i.

Moreover, when the bit line BL_i is unselected in this unset state of the isolation latch, the output signal of the NAND gate 63c becomes “H” and the output signal of the NAND gate 63g becomes “L”. The signal BLS outputted from the level shifter 64 becomes “L” and the signal BLUS becomes “H”, whereby the bit line BL_i is controlled by a potential of the signal line VUB.

On the other hand, when the signal CISO_SET is “H” and the signal CISO_RST is “L”, the isolation latch 63 attains the set state. If a column isolation signal, that is, a column address signal for setting the bit line to the floating state is inputted to the NAND gate 61 that is the column decoder, when the isolation latch is in the set state, the gate of the NMOS transistor 63d is inputted with “H”. In this case, since the MNOS transistor 63d and the NMOS transistor 63e are simultaneously turned on, the node cison is set to “L”.

When the isolation latch is set and the node cison is “L” (node ciso is “H”) , the output signal of the NAND gate 63c becomes “H” and the output signal of the NAND gate 63g becomes “H”. The signal BLS and the signal BLUS thus both become “L” and the bit line BL_i attains the floating state.

In this way, the column decoder 60 controls whether to connect the bit line BL_i (i=0-2) to the signal line DSA_i (i=0-2) or the signal line VUB, or to set the bit line BL_i to the floating state without connecting the bit line BL_i to either the signal line DSA_i or the signal line VUB.

FIGS. 6B and 6C show separate configuration examples of the column decoder 60. In the configurations of the column decoder 60 shown in FIGS. 6B and 6C, identical symbols are assigned to configurations similar to those of the column decoder 60 shown in FIG. 6A and descriptions thereof are omitted. The column decoders 60 shown in FIGS. 6B and 6C have a bit line select transistor configuration that differs from that of the column decoder 60 shown in FIG. 6A. FIG. 6A shows the case where one bit line is driven by the two NMOS transistors 4a and 6a. FIG. 6B shows the case where one bit line is driven by a PMOS transistor 4b and the NMOS transistor 6a, and FIG. 6C shows the case where one bit line is driven by the PMOS transistor 4b and the two NMOS transistors 4a and 6a.

FIG. 6B shows a circuit example when the bit line select transistor is configured by the PMOS transistor 4b and the NMOS transistor 6a. In this case, the level shifter 64 adopts a connection node of the PMOS transistor 64e and the NMOS transistor 64c as an output terminal. This output signal is inputted to a gate of the PMOS transistor 4b as the signal BLS. Using a PMOS transistor for the transistor between the signal line DSA_i and the bit line BL_i in this configuration enables an upper limit of transferrable voltage to be raised to a voltage applied to an Nwell of the PMOS transistor. At the same time, since a lower limit of the transferrable voltage is limited to a threshold voltage Vt of the PMOS transistor, applied voltages for the various operations need to be suitably controlled within this range.

FIG. 6C shows a circuit example when the bit line select transistor is configured by the NMOS transistor 4a, the PMOS transistor 4b, and the NMOS transistor 6a. In this case, the level shifter 64 outputs the signal BLS from a connection node of the PMOS transistor 64d and the NMOS transistor 64b to a gate of the transistor 4a, and outputs a signal BLSn from the connection node of the PMOS transistor 64e and the NMOS transistor 64c to a gate of the transistor 4b. Since this circuit has a CMOS configuration between the signal line DSA_i and the bit line BL_i, a voltage transferred to the bit line can be from 0 V to the voltage applied to the Nwell of the PMOS transistor.

As is clear from the above, circuit connections in the column decoder 60 may be suitably altered by the circuit configuration of the bit line select transistor. However, when the isolation latch is set to the set state, there is no change in the operation to set all transistors connected to the bit line BL_i to off, thereby setting the bit line BL_i to the floating state, whatever kind of column decoder 60 is adopted.

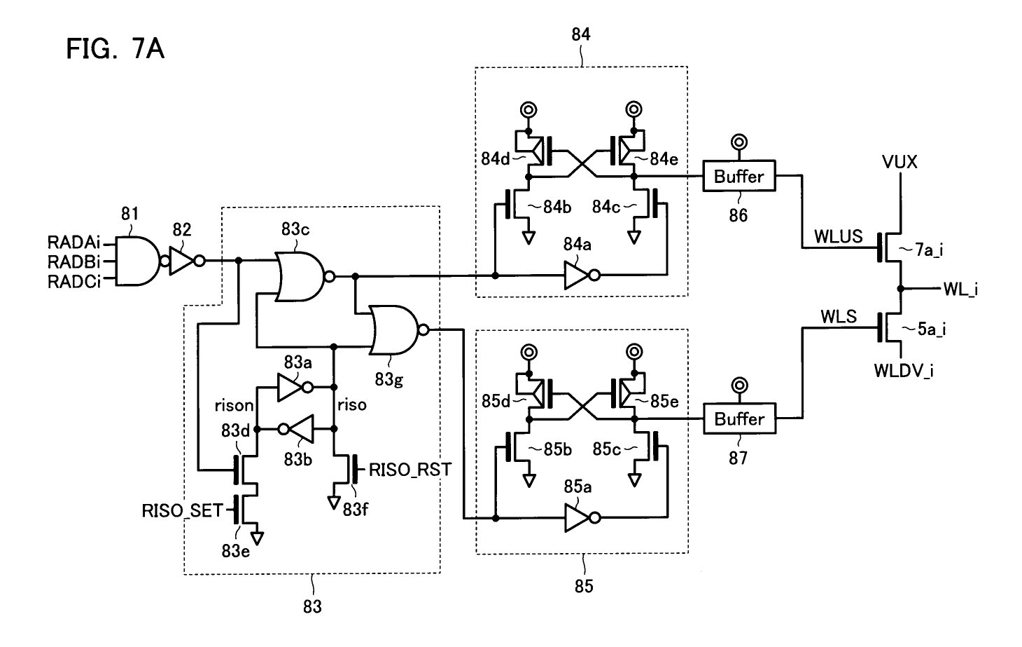

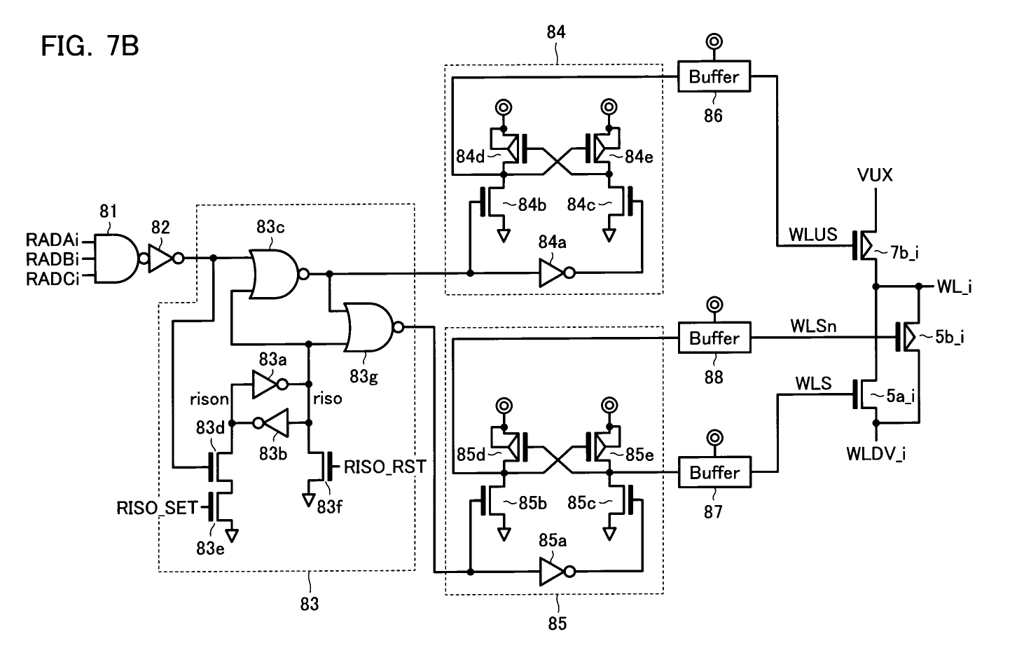

Next, details of the global row decoder 80 are described with reference to FIGS. 7A and 7B. The global row decoder 80 outputs signals WLS and WLUS to control conductive-state/non-conductive-state of the word line select transistors 5a and 7a. In addition, the global row decoder 80 functions as an isolation latch rendering the word line select transistors 5a and 7a both non-conductive to set the word lines WL_i (i=0-2) to the floating state.

(Configuration of the Global Row Decoder 80)

In FIG. 7A, NAND gate 81 is inputted with row address signals RADAi, RADBi, and RADCi. This NAND gate 81 functions as a row decoder. Although details are not shown here, the row address signals RADAi, RADBi, and RADCi are defined to be combinations of address signals that differ for the respective word lines. An output signal of the NAND gate 81 is inputted to a NOR gate 83c and agate of an NMOS transistor 83d, via an inverter 82. Inverters 83a and 83b, the NOR gate 83c and a NOR gate 83g, and the NMOS transistor 83d and NMOS transistors 83e and 83f configure an isolation latch 83.

The inverters 83a and 83b having input terminals and output terminals connected to each other configure a latch circuit. Note that the inverter 83a has its input terminal defined as node rison and its output terminal defined as node riso. Connected to a node riso side is the NMOS transistor 83f for resetting data of the isolation latch. Connected in series to a node rison side are the NMOS transistors 83d and 83e for setting isolation data in the isolation latch. A gate of the transistor 83d is connected to an output terminal of the inverter 82. A gate of the transistor 83f is inputted with a signal RISO_RST, and a gate of the transistor 83e is inputted with a signal RISO_SET. Moreover, sources of the transistors 83e and 83f are grounded. The isolation data held in the isolation latch is controlled by the signals RISO_RST and RISO_SET. The node rison of the isolation latch 83 is connected to respective input terminals of the NOR gates 83c and 83g.

An output signal of the NOR gate 83c is inputted to an NMOS transistor 84b and an inverter 84a that configure a level shifter 84. The level shifter 84 is configured by the inverter 84a, the NMOS transistor 84b and an NMOS transistor 84c, and PMOS transistors 84d and 84e. In addition, an output signal of the NOR gate 83g is inputted to an NMOS transistor 85b and an inverter 85a that configure a level shifter 85. The level shifter 85 is configured by the inverter 85a, the NMOS transistor 85b and an NMOS transistor 85c, and PMOS transistors 85d and 85e.

The level shifter 84 in the present embodiment is configured by the NMOS transistor 84b and the PMOS transistor 84d, the NMOS transistor 84c and the PMOS transistor 84e, and the inverter 84a. The gate of the transistor 84b is set as an input terminal of the level shifter 84, and a connection node between the PMOS transistor 84e and the NMOS transistor 84c is set as an output terminal of the level shifter 84. Similarly, the level shifter 85 is configured by the NMOS transistor 85b and the PMOS transistor 85d, the NMOS transistor 85c and the PMOS transistor 85e, and the inverter 85a. The gate of the transistor 85b is set as an input terminal of the level shifter 85, and a connection node between the PMOS transistor 85e and the NMOS transistor 85c is set as an output terminal of the level shifter 85. This circuit shows one example of a level shifter circuit, but the level shifter circuit need not necessarily be the shown circuit.

Signals outputted from the level shifters 84 and 85 are inputted as the signals WLUS and WLS to gates of NMOS transistors 5a_{—}i and 7a_{—}i, via buffer circuits 86 and 87, respectively. A signal line WLDV_i is connected to a drain of the transistor 5a_{—}i and a signal line VUX is connected to a drain of the transistor 7a_{—}i. A power supply voltage of the buffer circuits 86 and 87 is common to a power supply of the level shifters 84 and 85. The signals outputted from the level shifters 84 and 85 may be inputted to the gates of the NMOS transistors 5a_{—}i and 7a_{—}i via the buffer circuits 86 and 87, respectively, in this way, or without passing through buffer circuits, as in the column decoder 60 of FIG. 6A. The buffer circuits 86 and 87 should be inserted appropriately according to a capacitance of an output node.

(Operation of the Global Row Decoder 80)

When the isolation latch 83 is in an unset state, the global row decoder 80 connects the word line WL_i (i=0-2) to the signal line WLDV_i (i=0-2) or the signal line VUX. On the other hand, when the isolation latch 83 is in a set state, the global row decoder 80 performs control to set the word line WL_i to the floating state, without connecting the word line WL_i to either the signal line WLDV_i or the signal line VUX. The circuit configuration of the global row decoder 80 is configured such that control of the potential of the word line WL_i is performed by signals inputted to gate terminals of the NMOS transistors 5a and 7a and by a potential of the signal line WLDV connected to source terminals of the NMOS transistors 5a and 7a.

When the signal RISO_SET is “L” and the signal RISO_RST is “H”, the isolation latch 83 sets the node riso to “L” and the node rison to “H”. In this case, the isolation latch attains the unset state, whereby the NOR gates 83c and 83g output a signal according to an output signal of the NAND gate 81 that is the row decoder.

When the signals inputted to the gate terminals cause the word line WL_i to be unselected in this unset state of the isolation latch, the output signal of the NOR gate 83c becomes “H” and the output signal of the NOR gate 83g becomes “L”. The signal WLUS outputted from the level shifter 84 becomes “H” and the signal WLS outputted from the level shifter 85 becomes “L”, whereby the word line WL_i is controlled by a potential of the signal line VUX.

Moreover, when the signals inputted to the gate terminals cause the word line WL_i to be selected in this unset state of the isolation latch, an output signal of the NOR gate 83c becomes “L” and an output signal of the NOR gate 83g becomes “H”. The signal WLUS outputted from the level shifter 84 becomes “L” and the signal WLS outputted from the level shifter 85 becomes “H”, whereby the selected word line WL_i is controlled by a potential of the signal line WLDV_i. Here, the potential of the signal line WLDV is controlled by the local row decoder 90. In the local row decoder 90, the signal line WLDV connected to the unselected word line is set to “H”. At this time, the potential of the signal line WLDV is set to be identical to that of the signal line VUX. Moreover, in the local row decoder 90, the signal line WLDV connected to the selected word line is set to “L”. At this time, the potential of the signal line WLDV is set to the selected word line voltage (for example, 0 V). This potential of the signal line WLDV is applied to the word line WL_i via the transistor 5a.

On the other hand, when the signal RISO_SET is “H” and the signal RISO_RST is “L”, the isolation latch 83 attains the set state. If a row isolation signal, that is, a row address signal for setting the word line to the floating state is inputted to the NAND gate 81 that is the row decoder, when the isolation latch is in the set state, the gate of the NMOS transistor 83d is inputted with “H”. In this case, since the MNOS transistor 83d and the NMOS transistor 83e are simultaneously turned on, the node rison is set to “L”.

When the isolation latch is set and the node rison is “L” (node riso is “H”), the output signal of the NOR gate 83c becomes “L” and the output signal of the NOR gate 83g becomes “L”. The signal WLS and the signal WLUS thus both become “L” and the word line WL_i attains the floating state.

In this way, the global row decoder 80 controls whether to connect the word line WL_i (i=0-2) to the signal line WLDV_i (i=0-2) or the signal line VUX, or to set the word line WL_i to the floating state without connecting the word line WL_i to either the signal line WLDV_i or the signal line VUX.

FIG. 7B shows a separate configuration example of the global row decoder 80. In the configuration of the global row decoder 80 shown in FIG. 7B, identical symbols are assigned to configurations similar to those of the global row decoder 80 shown in FIG. 7A and descriptions thereof are omitted. The global row decoder 80 shown in FIG. 7B has a word line select transistor configuration that differs from that of the global row decoder 80 shown in FIG. 7A. FIG. 7A shows the case where one word line is driven by the two NMOS transistors 5a and 7a. FIG. 7B shows the case where one word line is driven by the NMOS transistor 5a and two PMOS transistors 5b and 7b.

FIG. 7B shows a circuit example when the word line select transistor is configured by the NMOS transistor 5a and the PMOS transistors 5b and 7b. In this case, the level shifter 84 adopts a connection node of the PMOS transistor 84d and the NMOS transistor 84b as an output terminal. The signal outputted from the level shifter 84 is inputted via the buffer circuit 86 to a gate of the PMOS transistor 7b as the signal WLUS. In addition, the level shifter 85 outputs the signal WLS from a connection node of the PMOS transistor 85e and the NMOS transistor 85c to the gate of the transistor 5a via the buffer circuit 87. The level shifter 85 also outputs a signal WLSn from a connection node of the PMOS transistor 85d and the NMOS transistor 85b to a gate of the PMOS transistor 5b via the buffer circuit 88. This configuration enables a range of voltage transferrable to the word line WL i to be broadened, similarly to the aforementioned column decoder 60.

Circuit connections in the global row decoder 80 may be suitably altered by the circuit configuration of the word line select transistor. However, when the isolation latch is set to the set state, all transistors connected to the word line WL_i are set to off, thereby setting the word line WL_i to the floating state, whatever kind of global row decoder 80 is adopted.

### Operation of the Semiconductor Memory Device in Accordance with the First Embodiment

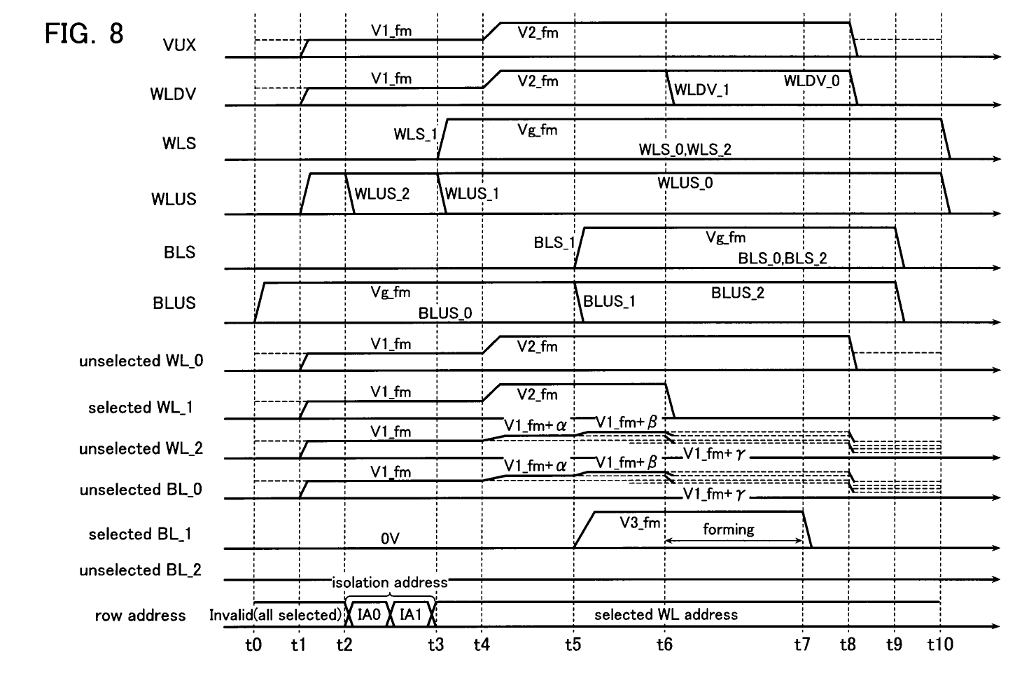

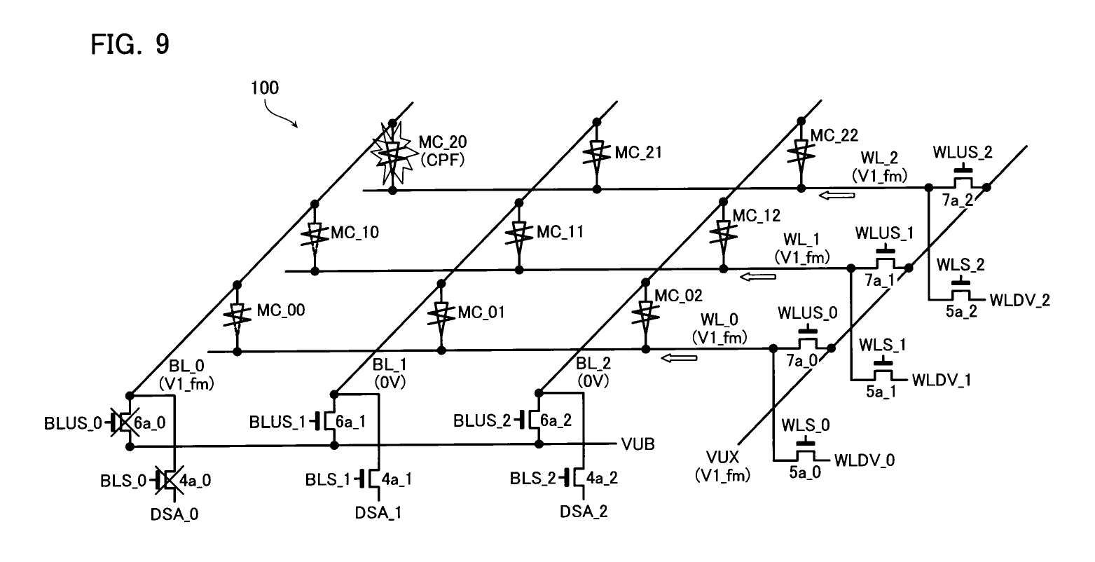

Next, the forming operation in the resistive memory device according to the present embodiment is described with reference to FIGS. 8-12. An operation to form the memory cell MC_11 shown in FIGS. 9-12 is taken as an example herein the description. The memory cell MC_11 is the memory cell at the crossing-point of the word line WL_1 and the bit line BL_1.

(Forming Operation in the Resistive Memory Device)

FIG. 8 is a timing chart for during the forming operation in the resistive memory device, and FIGS. 9-12 are views showing a voltage-application state in the memory cell array 100 at specific times during the forming operation. In the present embodiment, it is assumed that a CPF checking operation is performed prior to the forming operation, whereby the memory cell MC_20 is detected as a CPF. The address of this CPF, along with addresses of the bit line and word line connected to the CPF, are stored as a defect address in a register circuit or the like capable of temporary data storage. The forming operation is then performed sequentially on the memory cells in regions excluding those addresses.

By time t0 in the forming operation, the bit line BL_0 that includes the CPF memory cell MC_20 is set to the floating state, as shown in FIG. 8. That is, the isolation latch of the bit line BL_0 in the column decoder 60 is set to the set state, whereby the bit line BL_0 is set to the floating state based on the column address signal stored as the defect address. The bit line BL_0 is held constantly in the floating state for the remainder of the forming operation. Here, the potential of the bit line BL_0 during the forming operation is the same as the potential of the word line WL_2 due to short-circuiting by the CPF memory cell MC_20.

Next, at time t0, the other bit lines BL_1 and BL_2 not set to the floating state are set to the unselected state. As shown in FIG. 8, the signal BLUS (BLUS_1 and BLUS_2) inputted to gates of the bit line select transistors 6a_1 and 6a_2 is raised to a certain voltage Vg_fm, and the signal BLS (BLS_0-BLS_2) is held at 0 V. The potential of the signal line VUB is then set to an unselected voltage (for example, 0 V). Bit lines other than the bit line BL_0 that includes the CPF memory cell MC_20, namely the bit lines BL_1 and BL_2, are thereby held at the unselected voltage 0 V. The word lines WL_0-WL_2 are also each maintained at a voltage 0 V at this time.

Next, at time t1, all the global row decoders 80 set the signal WLS_i to “L” and the signal WLUS_i to “H”, thereby turning off the word line select transistors 5a and turning on the transistors 7a. Additionally at time t1, the signal line VUX and the signal line WLDV are applied with a voltage V1_fm. As a result, all the word lines WL are charged to the potential V1_fm of the signal line VUX, via the transistors 7a. Here, the bit line BL_0 is also charged to the voltage V1_fm due to short-circuiting with the word line WL_2 caused by the CPF memory cell MC_20. FIG. 9 shows the voltage-application state in the memory cell array at time t1.

Note that the voltage V1_fm is a voltage having a value greater than 0 V and less than a forming voltage V3_fm applied to the selected bit line BL_1 as described hereafter. The word line WL_2 and bit line BL_0 connected to the CPF memory cell MC_20 are pre-charged to this voltage V1_fm. With regards to both a difference between the voltage 0 V and the voltage V1_fm and a difference between the voltage V3_fm to be described hereafter and the voltage V1_fm, the voltage V1_fm is set so as not to cause forming of the memory cells MC. The voltage value of the voltage V1_fm is typically set to a value about half that of the voltage V3_fm to be described hereafter.

Next, at time t2, relevant isolation address signals IA0 and IA1 are inputted to the corresponding global row decoder 80 to perform isolation of the word line WL_2 that includes the CPF. The isolation latch in the global row decoder 80 is set based on these isolation address signals. In the example shown in FIG. 8, isolation of the word line WL_2 is performed by the two row address signals IA0 and IA1. When the isolation latch of the global row decoder 80 is set, the signal WLS_2 becomes “L” and the signal WLUS_2 becomes “L”, whereby the word line WL_2 that includes the CPF memory cell MC_20 is set to the floating state.

Next, at time t3, the address of the selected word line WL_1 connected to the selected memory cell MC_11 that is subject to the forming operation is inputted to the corresponding global row decoder 80. The global row decoder 80 corresponding to the selected word line WL_1 outputs signal WLS_1=“H” and signal WLUS_1=“L”, thereby connecting the selected word line WL_1 to the signal line WLDV. On the other hand, the unselected word line WL_0 has the signal WLS_0 set to “L” and the signal WLUS_0 set to “H”, thereby remaining connected to the signal line VUX.

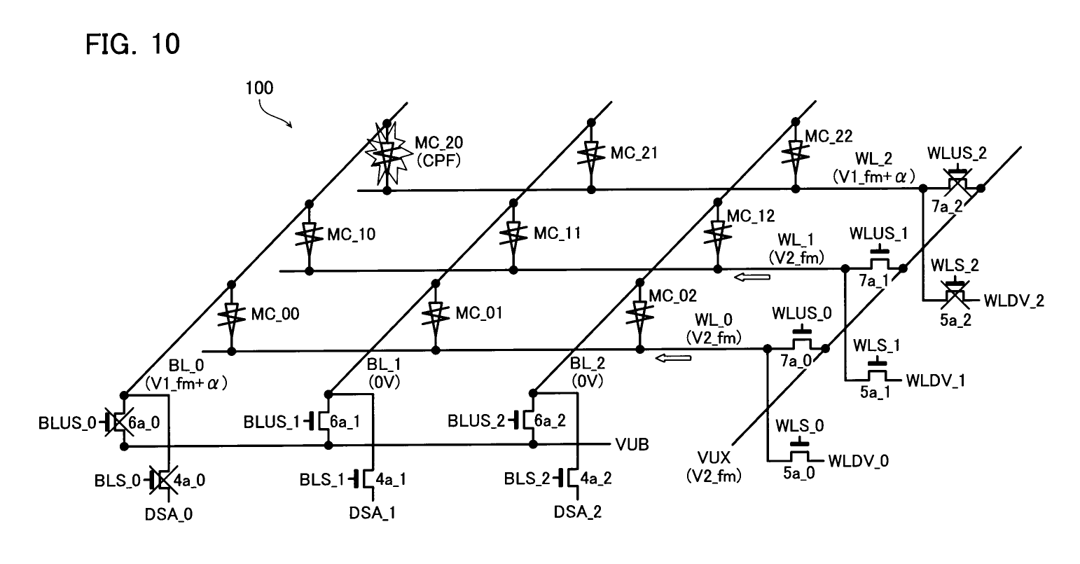

Next, at time t4, the voltage applied to the signal line VUX and the signal line WLDV is changed to the voltage V2_fm. The voltage V2_fm from the signal line VUX is applied to the word line WL_0 via the word line select transistor 7a_0, and the voltage V2_fm from the signal line WLDV_1 is applied to the word line WL_1 via the word line select transistor 5a_1. In this way, word lines other than the word line WL_2 set to the floating state, namely the word lines WL_0 and WL_1, are applied with the unselected word line voltage V2_fm during the forming operation. The voltage V2_fm may be the same voltage as the forming voltage V3_fm applied later to the selected bit line BL_1, or may be a slightly lower voltage than the forming voltage V3_fm. The voltage V2_fm is set to a magnitude that does not cause forming of the memory cell MC_01. At this time, the potential of the word line WL_2 which is in a floating state due to isolation is raised to due to coupling with an adjacent word line (here, word line WL_1), thereby becoming a voltage V1_fm+α. In addition, the bit line BL_0 also becomes the voltage V1_fm+α. FIG. 10 shows the voltage-application state in the memory cell array at time t4.

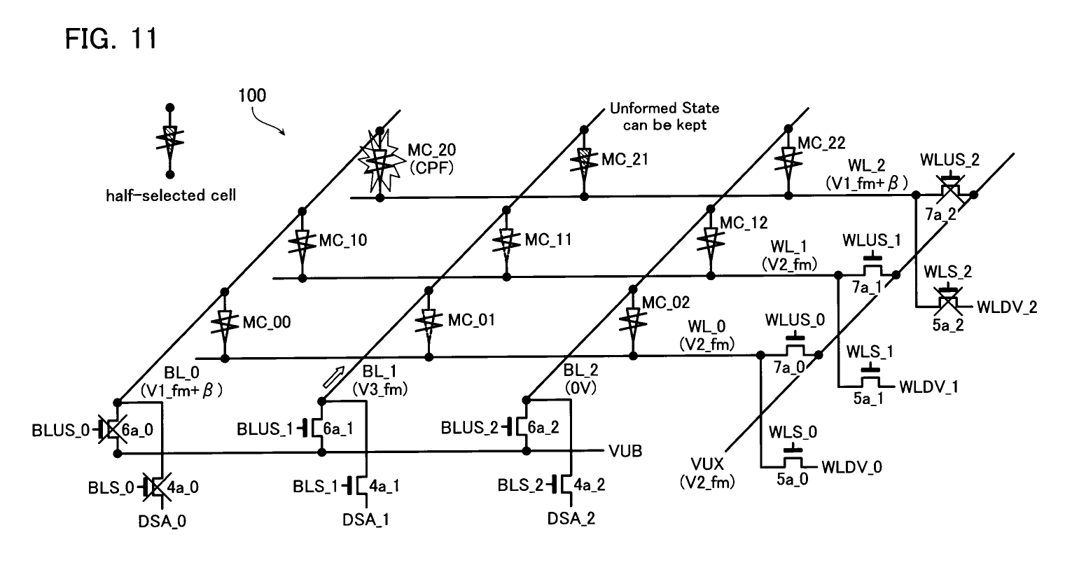

Next, at time t5, the selected bit line BL_1 is selected by the column decoder 60. The column decoder outputs signal BLS_1=“H” and signal BLUS_1=“L”, thereby connecting the selected bit line BL_1 to the signal line DSA. On the other hand, the unselected bit line BL_2 has the signal BLS_2 set to “L” and the signal BLUS_2 set to “H”, thereby remaining connected to the signal line VUB. In this state, the signal line DSA is applied with the forming voltage V3_fm. The forming voltage V3_fm from the signal line DSA is applied to the selected bit line BL_1 via the bit line select transistor 4a_1. Now, if the bit line BL_1 next to the bit line BL_0 which is in the floating state is applied with the voltage V3_fm, then the potential of that bit line BL_0 becomes V1_fm+β due to coupling. Moreover, the word line WL_2 also becomes the voltage V1_fm+β. FIG. 11 shows the voltage-application state in the memory cell array at time t5.

Here, the memory cells MC_00, MC_10, MC_02, MC_12, and MC_22 are in the reverse bias state. In addition, the memory cells MC_01 and MC_11 are in the non-bias state (voltage V3_fm=voltage V2_fm) or a weak forward bias state (voltage V3_fm>voltage V2_fm). Furthermore, the memory cell MC_21 is applied with a forward bias potential difference V3_fm−(V1_fm+β) from the bit line BL_1 (voltage V3_fm) to the word line WL_2 (voltage V1_fm+β). However, suitable adjustment of the voltage V1_fm pre-charged to the word line WL at time t1 allows the memory cell MC_21 to be held unchanged in the unformed state. This memory cell MC_21 is assumed to be in a half-selected state and shown by the symbol in FIG. 11.

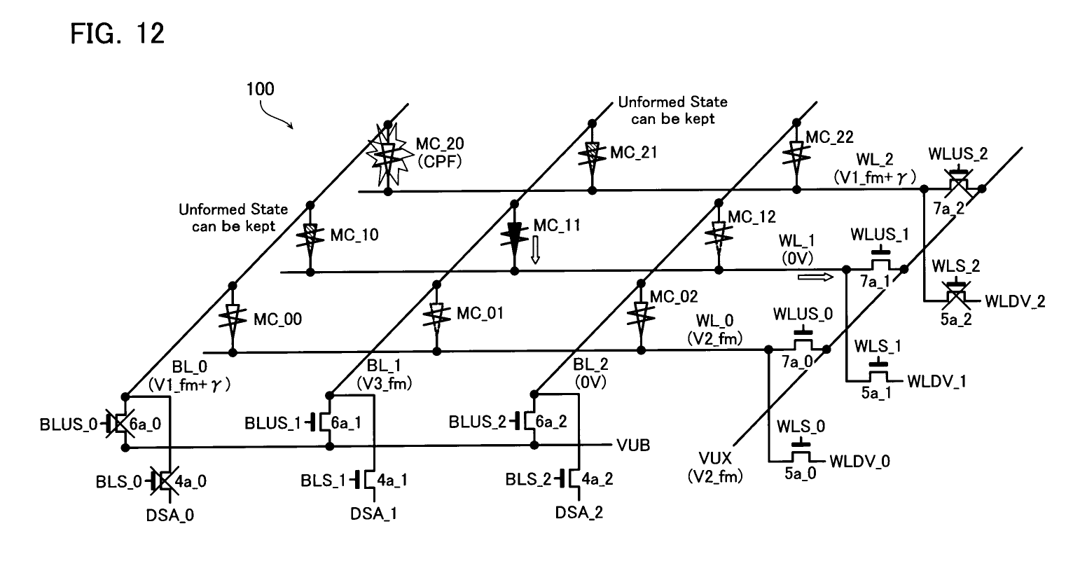

Next, at time t6, the voltage applied to the signal line WLDV_1 corresponding to the selected word line WL_1 is changed to the selected word line voltage 0 V. The selected word line WL_1 is thereby discharged to the voltage 0 V via the word line select transistor 5a_1. The selected memory cell MC_11 is applied with a potential difference required for the forming operation from the bit line BL_1 (voltage V3_fm) to the word line WL_1 (voltage 0 V). Subsequently, when a certain time elapses, a filament is formed, whereby the memory cell becomes functioning as a memory element. Now, if the word line WL_2 which is in the floating state and the selected word line WL_1 are adjacent, the word line WL_2 attains the voltage V1_fm+y due to effects of coupling when the selected word line WL_1 is discharged. In addition, the bit line BL_0 also attains the voltage V1_fm+γ. The voltages of the word line WL_2 and the bit line BL_0 during the forming operation change according to whether or not they are adjacent to the selected bit line BL_1 and the selected word line WL_1, and are therefore shown in FIG. 8 with variations added. Furthermore, FIG. 12 shows the voltage-application state in the memory cell array at time t6.

Here, the memory cells MC_00, MC_02, and MC_22 are in the reverse bias state and the memory cells MC_01 and MC_12 are in the non-bias state or a weak forward bias state. Furthermore, the memory cell MC_10 is applied with a forward bias potential difference V1_fm+γ from the bit line BL_0 (voltage V1_fm+γ) to the word line WL_1 (voltage 0 V). However, suitable adjustment of the voltage V1_fm pre-charged to the word line WL at time t1 allows the memory cell MC_10 to be held unchanged in the unformed state. This memory cell MC_10 is assumed to be in a half-selected state and shown by the symbol in FIG. 12.

At time t7, discharging of the bit lines and word lines and changing of selection states of the decoders and so on are executed sequentially to complete the forming operation. When the selected memory cell is switched and the forming operation continued, the isolation latches on the word line WL side should be reset and the aforementioned operation executed repeatedly.

### Advantages of the Semiconductor Memory Device in Accordance with the First Embodiment

During the forming operation in the resistive memory device in accordance with the present embodiment, the memory cells connected to the bit line BL_0 and word line WL_2 that include the CPF can be held in the unformed state while the other normal memory cells undergo forming.

The potential of the word line WL_2 and bit line BL_0 that include the CPF, namely the certain pre-charge potential V1_fm charged by time t2, rises and falls due to coupling during the subsequent operation. However, since the value of the voltage V1_fm can be changed and thereby adjusted, it is possible to exercise control to prevent forming of the memory cells connected to the word line WL_2 and the bit line BL_0 that include the CPF. In addition, the certainty with which unselected memory cells can be prevented from undergoing the forming operation is improved by taking such measures as unilaterally limiting the bit lines and word lines that exert coupling on the floating state bit lines and word lines (for example, setting at least two or more bit lines and word lines adjacent to the floating state bit lines and word lines to the floating state, and so on).

In the present embodiment, the defect address data to be set in the isolation latch is assumed to be held in a certain nonvolatile storage means. However, since data in the isolation latch is not stored when the power supply is shut down, the defect address data corresponding to the CPF which is stored in the certain nonvolatile storage means must be read and written to the isolation latch when the power supply is turned on.

### Second Embodiment

### Configuration of a Semiconductor Memory Device in Accordance with a Second Embodiment

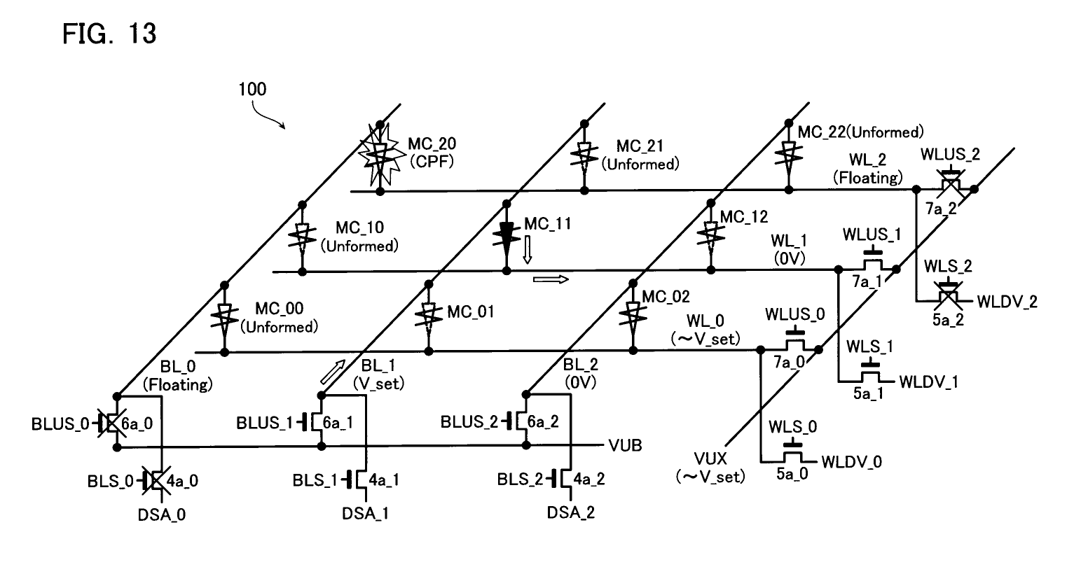

Next, a second embodiment of the present invention is described with reference to FIGS. 13-15. Configurations of a memory mat MAT, a column decoder 60, a global row decoder 80, and so on, in a resistive memory device of the present embodiment are similar to those in the aforementioned resistive memory device of the first embodiment. In the present embodiment, operation of the resistive memory device using the column decoder 60 and the global row decoder 80 having isolation latches is described.

### Operation of the Resistive Memory Device in Accordance with the Second Embodiment

A setting operation in the resistive memory device in accordance with the present embodiment is described with reference to FIG. 13. It is assumed here that, in the memory cell array 100 of the resistive memory in accordance with the present embodiment, the memory cells connected to the bit line BL_0 and the word line WL_2 that include the CPF are in the unformed state which is the constant high-resistance state where the resistance state does not change.

In FIG. 13, the selected memory cell on which the setting operation is executed is memory cell MC_11. The selected bit line BL and selected word line WL are the bit line BL_1 and word line WL_1, and these are applied with the selected bit line voltage V_set and the selected word line voltage (for example, 0 V), respectively. The unselected bit lines BL and unselected word lines WL are the bit line BL_2 and the word line WL_0, and these are applied with the unselected bit line voltage (for example, 0 V) and the unselected word line voltage V_set, respectively.

In the setting operation in the resistive memory device of the present embodiment, the bit line BL_0 and the word line WL_2 that include the CPF are set to the floating state. Isolation of the bit line BL_0 and the word line WL_2 is realized by the aforementioned column decoder 60 and global row decoder 80.

(Advantages of the Semiconductor Memory Device in Accordance with the Second Embodiment)

In the resistive memory device in accordance with the present embodiment, the memory cells MC_21 and MC_10 are memory cells in the unformed state. As a result, a current flowing out of the selected bit line BL_1 to the word line WL_2 that includes the CPF via the memory cell MC_21 is negligibly small during the setting operation. In addition, a current flowing into the selected word line WL_1 from the unselected bit line BL_0 via the memory cell MC 10 is also negligibly small. Therefore, the voltage applied to the selected bit line BL_1 and the selected word line WL_1 is unaffected even if the memory cell array 100 includes the bit line BL_0 and the word line WL_2 in the floating state.

In this way, by setting the memory cells connected to the bit line BL_0 and word line WL_2 that include the CPF to the unformed state and also by setting the bit line BL_0 and word line WL_2 that include the CPF to the floating state during the setting operation, it is possible to apply a desired setting voltage V_set to the selected memory cell MC_11. Accordingly, the operation can be executed normally even if a CPF exists in the memory cell array 100.

### Another Example of Operation of the Semiconductor Memory Device in Accordance with the Second Embodiment

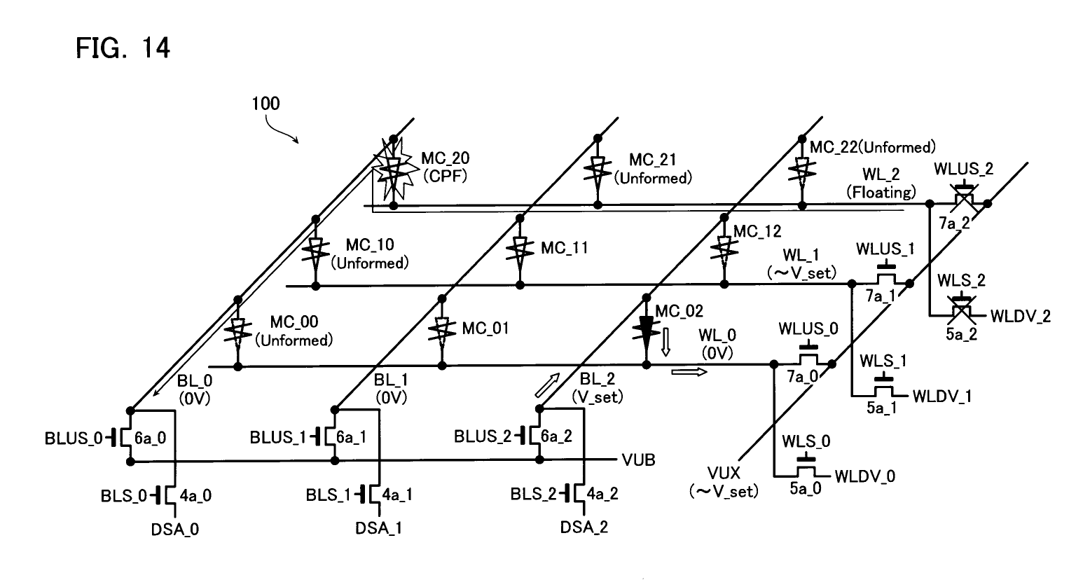

Next, another example of the setting operation in the resistive memory device in accordance with the present embodiment is described with reference to FIG. 14. Configurations of a memory mat MAT, a column decoder 60, a global row decoder 80, and so on, in a resistive memory device of the present example are similar to those in the aforementioned resistive memory device of the first embodiment. It is likewise assumed here that, in the memory cell array 100, the memory cells connected to the bit line BL_0 and the word line WL_2 that include the CPF are in the unformed state which is the constant high-resistance state where the resistance state does not change.

In FIG. 14, the selected memory cell on which the setting operation is executed is memory cell MC_02. The selected bit line BL and selected word line WL are the bit line BL_2 and word line WL_0, and these are applied with the selected bit line voltage V_set and the selected word line voltage (for example, 0 V), respectively. The unselected bit lines BL and unselected word lines WL are the bit line BL_1 and the word line WL_1, and these are applied with the unselected bit line voltage (for example, 0 V) and the unselected word line voltage V_set, respectively.

In the setting operation in the resistive memory device of the present example, the word line WL_2 that includes the CPF is set to the floating state. Isolation of the word line WL_2 is executed by the aforementioned global row decoder 80. In contrast, the bit line BL_0 that includes the CPF is applied with the unselected bit line voltage 0 V, similarly to the unselected bit line BL_1.

In the resistive memory device of the present example, the word line WL_2 is short-circuited with the bit line BL_0 due to the CPF and is discharged to the potential 0 V of the signal line VUB. However, the memory cell MC_22 is a memory cell in the unformed state. As a result, a current flowing out of the selected bit line BL_2 to the word line WL_2 that includes the CPF via the memory cell MC_22 is negligibly small during the setting operation. Therefore, the voltage applied to the selected bit line BL_2 and the selected word line WL_0 is unaffected even if the memory cell array 100 includes the word line WL_2 in the floating state.

In this way, by setting the memory cells connected to the bit line BL_0 and word line WL_2 that include the CPF to the unformed state and also by setting only the word line WL_2 that includes the CPF to the floating state during the setting operation, it is possible to apply a desired setting voltage V_set to the selected memory cell MC_02. Accordingly, the operation can be executed normally even if a CPF exists in the memory cell array 100.

### Yet another Example of Operation of the Semiconductor Memory Device in Accordance with the Second Embodiment

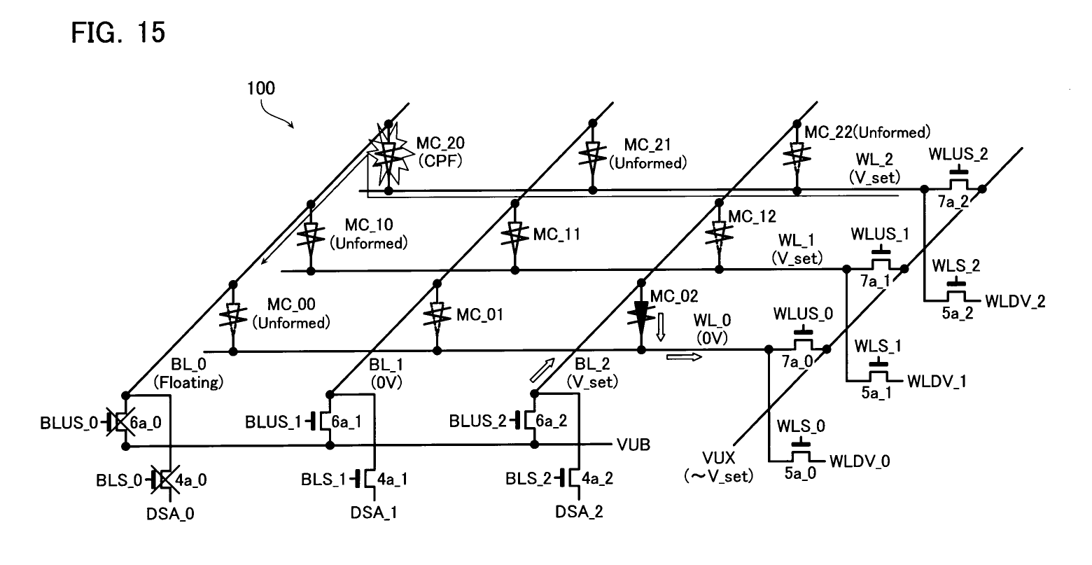

Next, yet another example of the setting operation in the resistive memory device in accordance with the present embodiment is described with reference to FIG. 15. Configurations of a memory mat MAT, a column decoder 60, a global row decoder 80, and so on, in a resistive memory device of the present example are similar to those in the aforementioned resistive memory device of the first embodiment. It is likewise assumed here that, in the memory cell array 100, the memory cells connected to the bit line BL_0 and the word line WL_2 that include the CPF are in the unformed state which is the constant high-resistance state where the resistance state does not change.

In FIG. 15, the selected memory cell on which the setting operation is executed is memory cell MC_02. The selected bit line BL and selected word line WL are the bit line BL_2 and word line WL_0, and these are applied with the selected bit line voltage V_set and the selected word line voltage (for example, 0 V), respectively. The unselected bit lines BL and unselected word lines WL are the bit line BL_1 and the word line WL_1, and these are applied with the unselected bit line voltage (for example, 0 V) and the unselected word line voltage V_set, respectively.

In the setting operation in the resistive memory device of the present example, the bit line BL_0 that includes the CPF is set to the floating state. Isolation of the bit line BL_0 is executed by the aforementioned column decoder 60. In contrast, the word line WL_2 that includes the CPF is applied with the unselected word line voltage V_set, similarly to the unselected word line WL_1.

In the resistive memory device of the present example, the bit line BL_0 is short-circuited with the word line WL_2 due to the CPF and is charged to the potential V_set of the signal line VUX. However, the memory cell MC_00 is a memory cell in the unformed state. As a result, a current flowing out of the charged bit line BL_0 to the selected word line WL_0 via the memory cell MC_00 is negligibly small during the setting operation. Therefore, the voltage applied to the selected bit line BL_2 and the selected word line WL_0 is unaffected even if the memory cell array 100 includes the bit line BL_0 in the floating state.

In this way, by setting the memory cells connected to the bit line BL_0 and word line WL_2 that include the CPF to the unformed state and also by setting only the bit line BL_0 that includes the CPF to the floating state during the setting operation, it is possible to apply a desired setting voltage V_set to the selected memory cell MC_02. Accordingly, the operation can be executed normally even if a CPF exists in the memory cell array 100.

This concludes description of embodiments of the present invention, but it should be noted that the present invention is not limited to the above-described embodiments, and that various alterations, additions, and so on, are possible within a range not departing from the scope and spirit of the invention. For example, although the setting operation was used to describe operation of the resistive memory device in the second embodiment, it is also possible to use a resetting operation and a read operation where a value of an applied voltage is changed without changing a voltage-application state to the bit lines and word lines. Likewise in these cases, by setting the memory cells connected to the bit line and word line that include the CPF to the unformed state and also by setting at least one of the bit line and word line that include the CPF to the floating state during the resetting operation and the read operation, it is possible to apply a desired voltage to the selected memory cell.

What is claimed is:

1. A semiconductor memory device, comprising:
a memory cell array having memory cells disposed at a crossing-point of a plurality of first lines and a plurality of second lines, each of the memory cells being configured by a rectifier and a variable resistor connected in series; and
a control circuit configured to apply a first voltage to selected one of the first lines, and to apply a second voltage to selected one of the second lines, such that a certain potential difference is applied to selected one of the memory cells disposed at the crossing-point of the selected one of the first lines and the selected one of the second lines,
the control circuit comprising:
a first isolation latch circuit configured to set the first lines to a floating state without any voltage being applied thereto, based on an address signal; and
a second isolation latch circuit configured to set the second lines to the floating state without any voltage being applied thereto, based on an address signal,
during execution of a forming operation configured to render a resistance state of the variable resistor capable of transition by applying a certain potential difference to the selected one of the memory cells, the first and second isolation latch circuits setting one of the first lines and one of the second lines to which a defective memory cell is connected to the floating state, the defective memory cell being one of the memory cells that allows a current to flow due to application of a voltage in a reverse direction as well as in a forward direction.

2. The semiconductor memory device according to claim 1,
wherein, prior to execution of the forming operation on the selected one of the memory cells, the one of the first lines and the one of the second lines to which the defective memory cell is connected are pre-charged to a pre-charge voltage having a voltage value lower than a voltage value of the first voltage and higher than a voltage value of the second voltage.

3. The semiconductor memory device according to claim 2,
wherein the voltage value of the pre-charge voltage is set to a voltage value such that a potential difference between the first voltage and the pre-charge voltage does not cause the memory cells to undergo the forming operation, and such that a potential difference between the second voltage and the pre-charge voltage does not cause the memory cells to undergo the forming operation.

4. The semiconductor memory device according to claim 2,
wherein the voltage value of the pre-charge voltage is set to an intermediate value between a voltage value of the first voltage and a voltage value of the second voltage.

5. The semiconductor memory device according to claim 1,
wherein, prior to execution of the forming operation on the selected one of the memory cells, the control circuit sets the one of the first lines to which the defective memory cell is connected to the floating state,
pre-charges all of the second lines within the memory cell array to a pre-charge voltage having a voltage value lower than a voltage value of the first voltage and higher than a voltage value of the second voltage,
sets the one of the second lines to which the defective memory cell is connected to the floating state, and
applies a third voltage having a voltage value less than or equal to the voltage value of the first voltage to the second lines to which the defective memory cell is not connected, and
then executes the forming operation by applying the first voltage to the selected one of the first lines and applying the second voltage to the selected one of the second lines.

6. The semiconductor memory device according to claim 5,
wherein the voltage value of the third voltage is set to a voltage value such that a potential difference between the first voltage and the third voltage does not cause the memory cells to undergo the forming operation.

7. The semiconductor memory device according to claim 1,
wherein the first isolation latch circuit comprises a latch circuit configured by a first and a second inverter having input terminals and output terminals connected to each other, and
wherein, in the latch circuit, data is set based on the address signal and a setting signal, whereby the first lines are set to the floating state, and data is reset due to a resetting signal, whereby the first lines are connected to a signal line configured to apply a necessary voltage to the first lines.

8. The semiconductor memory device according to claim 1,
wherein the second isolation latch circuit comprises a latch circuit configured by a first and a second inverter having input terminals and output terminals connected to each other, and
wherein, in the latch circuit, data is set based on the address signal and a setting signal, whereby the second lines are set to the floating state, and data is reset due to a resetting signal, whereby the second lines are connected to a signal line configured to apply a necessary voltage to the second lines.

9. A semiconductor memory device, comprising:
a memory cell array having memory cells disposed at a crossing-point of a plurality of first lines and a plurality of second lines, each of the memory cells being configured by a rectifier and a variable resistor connected in series; and
a control circuit configured to apply a first voltage to selected one of the first lines, and to apply a second voltage to selected one of the second lines, such that a certain potential difference is applied to selected one of the memory cells disposed at the crossing-point of the selected one of the first lines and the selected one of the second lines,
the control circuit comprising:
a first isolation latch circuit configured to set the first lines to a floating state without any voltage being applied thereto, based on an address signal; and
a second isolation latch circuit configured to set the second lines to the floating state without any voltage being applied thereto, based on an address signal,
other of the memory cells connected to one of the first lines and one of the second lines to which a defective memory cell is connected being in an unformed state in which a resistance state of the variable resistor does not undergo transition, the defective memory cell being one of the memory cells that allows a current to flow due to application of a voltage in a reverse direction as well as in a forward direction, and
during execution of an operation by applying a certain voltage to the selected one of the memory cells, the first and second isolation latch circuits setting at least one of the one of the first lines and the one of the second lines to which the defective memory cell is connected to the floating state.

10. The semiconductor memory device according to claim 9,
wherein the first and second isolation latch circuits set both of the one of the first lines and the one of the second lines to which the defective memory cell is connected to the floating state.

11. The semiconductor memory device according to claim 9,
wherein the variable resistor on which there is executed a forming operation configured to render a resistance state of the variable resistor capable of transition takes at least two resistance states of a low-resistance state and a high-resistance state, and
wherein the variable resistor of the memory cells in the unformed state is constantly in the high-resistance state.

12. The semiconductor memory device according to claim 9,
wherein the first isolation latch circuit comprises a latch circuit configured by a first and a second inverter having input terminals and output terminals connected to each other, and
wherein, in the latch circuit, data is set based on the address signal and a setting signal, whereby the first lines are set to the floating state, and data is reset due to a resetting signal, whereby the first lines are connected to a signal line configured to apply a necessary voltage to the first lines.

13. The semiconductor memory device according to claim 9,
wherein the second isolation latch circuit comprises a latch circuit configured by a first and a second inverter having input terminals and output terminals connected to each other, and
wherein, in the latch circuit, data is set based on the address signal and a setting signal, whereby the second lines are set to the floating state, and data is reset due to a resetting signal, whereby the second lines are connected to a signal line configured to apply a necessary voltage to the second lines.

14. A method of operating a semiconductor memory device, the semiconductor memory device including a memory cell array having memory cells disposed at a crossing-point of a plurality of first lines and a plurality of second lines, each of the memory cells being configured by a rectifier and a variable resistor connected in series, and a control circuit configured to apply a first voltage to selected one of the first lines, and to apply a second voltage to selected one of the second lines, such that a certain potential difference is applied to selected one of the memory cells disposed at the crossing-point of the selected one of the first lines and the selected one of the second lines, the method comprising:
setting one of the first lines and one of the second lines to which a defective memory cell is connected to a floating state, the defective memory cell being one of the memory cells that allows a current to flow due to application of a voltage in a reverse direction as well as in a forward direction, and
executing a forming operation to render a resistance state of the variable resistor capable of transition by applying a certain potential difference to the selected one of the memory cells.

15. The method of operating a semiconductor memory device according to claim 14,
wherein, prior to execution of the forming operation on the selected one of the memory cells, pre-charging the one of the first lines and the one of the second lines to which the defective memory cell is connected to a pre-charge voltage having a voltage value lower than a voltage value of the first voltage and higher than a voltage value of the second voltage.

16. The method of operating a semiconductor memory device according to claim 15,
wherein the voltage value of the pre-charge voltage is set to a voltage value such that a potential difference between the first voltage and the pre-charge voltage does not cause the memory cells to undergo the forming operation, and such that a potential difference between the second voltage and the pre-charge voltage does not cause the memory cells to undergo the forming operation.

17. The method of operating a semiconductor memory device according to claim 15,
wherein the voltage value of the pre-charge voltage is set to an intermediate value between a voltage value of the first voltage and a voltage value of the second voltage.

18. The method of operating a semiconductor memory device according to claim 14,
wherein, prior to execution of the forming operation on the selected one of the memory cells,
setting the one of the first lines to which the defective memory cell is connected to the floating state,
pre-charging all of the second lines within the memory cell array to a pre-charge voltage having a voltage value lower than a voltage value of the first voltage and higher than a voltage value of the second voltage,
setting the one of the second lines to which the defective memory cell is connected to the floating state, and
applying a third voltage having a voltage value less than or equal to the voltage value of the first voltage to the second lines to which the defective memory cell is not connected, and
wherein the forming operation is then executed by applying the first voltage to the selected one of the first lines and applying the second voltage to the selected one of the second lines.

19. The method of operating a semiconductor memory device according to claim 18,
wherein the voltage value of the third voltage is set to a voltage value such that a potential difference between the first voltage and the third voltage does not cause the memory cells to undergo the forming operation.

20. The method of operating a semiconductor memory device according to claim 14,
wherein, prior to execution of the forming operation on the selected one of the memory cells, applying a voltage by the control circuit to the memory cells to detect the defective memory cell.
